(19) United States
(12) Patent Application Publication
(10) Pub. No.: US 2023/0342995 A1
(43) Pub. Date: Oct. 26, 2023

(54) PATCH-BASED MEDICAL IMAGE GENERATION FOR COMPLEX INPUT DATASETS

(71) Applicants: The General Hospital Corporation, Boston, MA (US); Trustees of Boston University, Boston, MA (US)

(72) Inventors: Neha Koonjoo, Boston, MA (US); Matthew S. Rosen, Somerville, MA (US); Bo Zhu, Palo Alto, CA (US); Danyal Fareed Bhutto, Boston, MA (US)

(21) Appl. No.: 18/304,974

(22) Filed: Apr. 21, 2023

Related U.S. Application Data
(60) Provisional application No. 63/333,407, filed on Apr. 21, 2022.

(51) Int. Cl. G06T 11/00; G06T 3/40; G06N 3/08

(52) U.S. Cl. CPC G06T 11/005; G06T 3/40; G06N 3/08; G06T 2210/41

(57) ABSTRACT

Systems, methods, and media for patch-based medical image generation for complex input datasets. Patch-based medical image generation can include creating a training dataset with an image patch and corresponding sensor data patch and training a neural network using the training dataset. Then, sensor data acquired from a patient using a medical imaging system can be applied as input to the neural network, and a medical image of the patient can be generated based on an output of the neural network.

### CROSS-REFERENCE TO RELATED APPLICATIONS

This application claims the benefit of and priority to U.S. Provisional Patent Application No. 63/334,407, filed Apr. 21, 2022, the entirety of which is incorporated by reference herein.

### STATEMENT REGARDING FEDERALLY SPONSORED RESEARCH

This invention was made with government support under Grant No. DGE-1840990 awarded by the National Science Foundation Graduate Research Fellowship and under Grant No. DGE-1633516NSF awarded by the National Science Foundation Research Traineeship Program: Understanding the Brain. The government has certain rights in the invention.

### BACKGROUND

The present disclosure relates generally to imaging and, more particularly, to systems, methods, and media for reconstructing medical images from acquired data. The field of medical imaging presents various constraints that are not present in more general fields such as general photography. For example, medical imaging may require appropriate transformation from the sensor or signal domain to the image domain. Improvements in medical imaging technology are generally desired across a wide range of different applications.

### SUMMARY

One aspect of the present disclosure is a method for medical imaging. The method includes collecting a first medical image of a first patient from a database; splitting the first medical image into a first image patch and a second image patch; applying a Fourier transform to the first image patch to transform the first image patch into a first sensor data patch; creating a training dataset comprising the first image patch and the first sensor data patch; training a neural network using the training dataset; after training the neural network using the training dataset, applying sensor data acquired from a second patient using a medical imaging system as an input to the neural network; generating a second medical image of the second patient based on an output of the neural network; and displaying the second medical image of the second patient for clinical analysis.

Another aspect of the present disclosure is a non-transitory computer-readable storage medium having instructions stored thereon that, when executed by at least one processor, cause the at least one processor to implement operations. The operations include collecting a first medical image of a first patient from a database; splitting the first medical image into a first image patch and a second image patch; applying a Fourier transform to the first image patch to transform the first image patch into a first sensor data patch; creating a training dataset comprising the first image patch and the first sensor data patch; training a neural network using the training dataset; after training the neural network using the training dataset, applying sensor data acquired from a second patient using a medical imaging modality as an input to the neural network; generating a second medical image of the second patient based on an output of the neural network; and displaying the second medical image of the second patient for clinical analysis.

Another aspect of the present disclosure is a system. The system includes a display, one or more sensors, one or more processors, and one or more non-transitory computer readable storage media having instructions stored thereon that, when executed by the one or more processors, cause the one or more processors to implement operations. The operations include collecting a first medical image of a first patient from a database; splitting the first medical image into a first image patch and a second image patch; applying a Fourier transform to the first image patch to transform the first image patch into a first sensor data patch; creating a training dataset comprising the first image patch and the first sensor data patch; training a neural network using the training dataset; after training the neural network using the training dataset, applying sensor data acquired from a second patient as an input to the neural network; generating a second medical image of the second patient based on an output of the neural network; and displaying the second medical image of the second patient for clinical analysis.

Another aspect of the present disclosure is a method for training a neural network for medical imaging. The method includes collecting a medical image of a patient from a database; splitting the medical image into at least a first image patch and a second image patch; applying a Fourier transform to the first image patch to transform the first image patch into a first sensor data patch; applying a Fourier transform to the second image patch to transform the second image patch into a second sensor data patch; creating a training dataset comprising the first image patch and the first sensor data patch, and the second image patch and the second sensor data patch; and training a neural network using the training dataset.

Another aspect of the present disclosure is a method for medical imaging. The method includes acquiring sensor data from a patient using a medical imaging system; splitting the sensor data from the patient into a first sensor data patch and a second sensor data patch; applying the first sensor data patch as an input to a neural network that has been trained using a training dataset comprising a set of input-output pairs, wherein each input-output pair of the set of input-output pairs comprises a sensor data patch and a corresponding image patch; receiving a first image patch as an output of the neural network responsive to applying the first sensor data patch as the input to the neural network; applying the second sensor data patch as the input to the neural network; receiving a second image patch as the output of the neural network responsive to applying the second sensor data patch as the input to the neural network; generating a medical image of the patient using both the first image patch and the second image patch; and causing the medical image of the patient to be displayed for clinical analysis.

### BRIEF DESCRIPTION OF THE DRAWINGS

FIG. 1 shows a diagram illustrating filtered back projection image reconstruction using x-ray transmission profiles, in accordance with some aspects of the disclosure.

FIG. 2A shows a graph illustrating a Fourier imaging scan pattern that can be used to reconstruct k-space data, in accordance with some aspects of the disclosure.

FIG. 2B shows a graph illustrating a projection reconstruction method that can sample k-space data as radial lines extending outward from the center of k-space, in accordance with some aspects of the disclosure.

FIG. 3A shows an illustration of an example x-ray computed tomography (CT) imaging system, in accordance with some aspects of the disclosure.

FIG. 3B shows a system diagram of the example x-ray CT imaging system of FIG. 3A, in accordance with some aspects of the disclosure.

FIG. 4A shows an illustration of another example x-ray CT imaging system, in accordance with some aspects of the disclosure.

FIG. 4B shows a system diagram of the example x-ray CT imaging system of FIG. 4A, in accordance with some aspects of the disclosure.

FIG. 5 shows a diagram of an example magnetic resonance imaging (MM) system, in accordance with some aspects of the disclosure.

FIG. 6 shows a diagram of an example imaging system that uses one or more image sensors to optically capture images, in accordance with some aspects of the disclosure.

FIG. 7 shows a diagram of an example ultrasound system, in accordance with some aspects of the disclosure.

FIG. 8 shows a flow diagram illustrating an example process for image reconstruction between a sensor domain and an image domain using a data-driven, manifold learning approach, in accordance with some aspects of the disclosure.

FIG. 9 shows a system diagram representing an example neural network model that can be used to reconstruct an image by transforming data from a sensor domain to an image domain, in accordance with some aspects of the disclosure.

FIG. 10 shows a flow diagram illustrating an example process for generating a training dataset that can be used to train the neural network model of FIG. 9, in accordance with some aspects of the disclosure.

FIG. 11 shows a flow diagram illustrating an example process for performing inference using the neural network model of FIG. 9 after the neural network model of FIG. 9 is trained based on the training dataset generated using the process of FIG. 10, in accordance with some aspects of the disclosure.

FIG. 12 shows a first series of medical images generated using different approaches, in accordance with some aspects of the disclosure.

FIGS. 13A-13B shows a first series of graphs plotting data associated with the medical images shown in FIG. 12, in accordance with some aspects of the disclosure.

FIG. 14 shows a second series of medical images generated using different approaches, in accordance with some aspects of the disclosure.

FIGS. 15A-15B shows a second series of graphs plotting data associated with the medical images shown in FIG. 14, in accordance with some aspects of the disclosure.

FIG. 16 shows a flow diagram illustrating an example process for medical imaging, in accordance with some aspects of the disclosure.

### DETAILED DESCRIPTION

Imaging is important to a wide range of industries and activities. From space exploration to oil exploration, imaging plays a key role in these endeavors. The modalities available for imaging are at least as diverse as the industries that employ them. For example, in the medical industry alone, a staggeringly large number of imaging modalities are employed in regular, clinical medicine. For example, to name but a few, magnetic resonance imaging (MM), computed tomography (CT) imaging, emission tomography imaging (including modalities such as positron emission tomography and single photon emission computed tomography), optical, x-ray fluoroscopy, and many, many others are utilized each day in modern medicine.

Regardless of the modality employed or the industry/application, reconstruction is a key process in any imaging process. In some settings, image reconstruction may be quite rudimentary or well settled. For example, image reconstruction for x-ray fluoroscopy generally includes translating attenuation values into contrast values in the digital image. Other modalities require much more complex reconstruction techniques.

In a computed tomography system, for example, an x-ray source projects a fan-shaped beam which is collimated to lie within an x-y plane of a Cartesian coordinate system, termed the “image plane.” The x-ray beam passes through the object being imaged, such as a medical patient, and impinges upon an array of radiation detectors. The intensity of the transmitted radiation is dependent upon the attenuation of the x-ray beam by the object and each detector produces a separate electrical signal that is a measurement of the beam attenuation. The attenuation measurements from all the detectors are acquired separately to produce what is called the “transmission profile”, “attenuation profile”, or “projection”. In x-ray fluoroscopy, this two-dimensional projection is translated into a single image.

The source and detector array in a CT system can be rotated on a gantry within the imaging plane and around the object so that the angle at which the x-ray beam intersects the object constantly changes. The transmission profile from the detector array at a given angle is referred to as a “view” and a “scan” of the object comprises a set of views made at different angular orientations during one revolution of the x-ray source and detector. In a 2D scan, data is processed to construct an image that corresponds to a two-dimensional slice taken through the object. The prevailing method for reconstructing an image from 2D data is referred to in the art as the filtered back projection technique. This image reconstruction process converts the attenuation measurements acquired during a scan into integers called “CT numbers” or “Hounsfield units”, which are used to control the brightness of a corresponding pixel on a display.

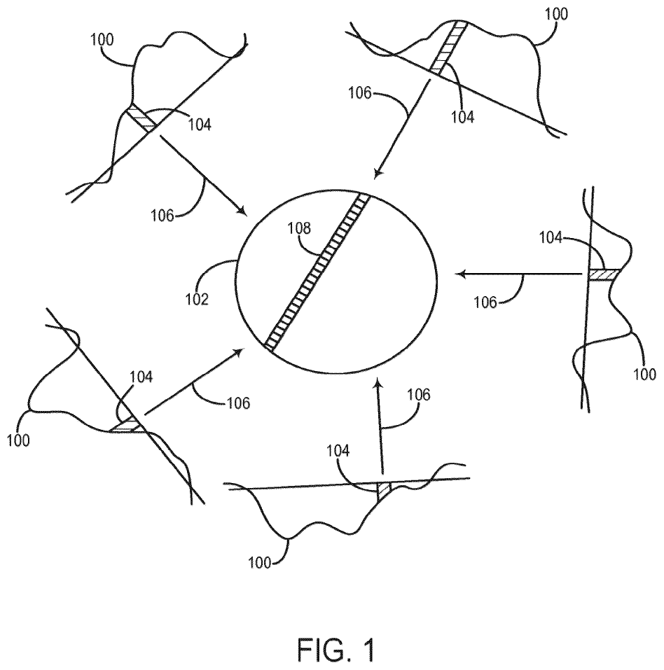

The filtered back projection image reconstruction method is the most common technique used to reconstruct CT images from acquired transmission profiles. As shown in FIG. 1, each acquired x-ray transmission profile 100 is back projected onto the field of view (FOV) 102 by projecting each ray sum 104 in the profile 100 through the FOV 102 along the same ray path that produced the ray sum 104 as indicated by arrows 106. In projecting each ray sum 104 in the FOV 102 we have no a priori knowledge of the subject and the assumption is made that the x-ray attenuation in the FOV 102 is homogeneous and that the ray sum should be distributed equally in each pixel through which the ray path passes. For example, a ray path 108 is illustrated in FIG. 1 for a single ray sum 104 in one transmission profile 100 and it passes through N pixels in the FOV 102. The attenuation value, P, of this ray sum 104 is divided up equally between these N pixels:

$${μ}_{n} = \frac{( P \times 1 )}{N}$$

In the above equation, μₙ is the attenuation value distributed to the n^{th} pixel in a ray path having N pixels. Clearly, the assumption that attenuation in the FOV 102 is homogeneous is not correct. However, as is well known in the art, if certain corrections are made to each transmission profile 100 and a sufficient number of profiles are acquired at a corresponding number of projection angles, the errors caused by this faulty assumption are minimized and image artifacts are suppressed. In a typical filtered back projection method of image reconstruction, anywhere from 400 to 1000 views are typically required to adequately suppress image artifacts in a 2D CT image.

MRI uses the nuclear magnetic resonance (NMR) phenomenon to produce images. When a substance such as human tissue is subjected to a uniform magnetic field (polarizing field B0), the individual magnetic moments of the spins in the tissue attempt to align with this polarizing field, but precess about it in random order at their characteristic Larmor frequency. If the substance, or tissue, is subjected to a magnetic field (excitation field B1) which is in the x-y plane and which is near the Larmor frequency, the net aligned moment, M_{Z}, may be rotated, or “tipped”, into the x-y plane to produce a net transverse magnetic moment M_{XY}. A signal is emitted by the excited spins, and after the excitation signal B1 is terminated, this signal may be received and processed to form an image.

When utilizing these signals to produce images, magnetic field gradients (G_{X}, G_{Y}, and G_{Z}) are employed. Typically, the region to be imaged is scanned by a sequence of measurement cycles in which these gradients vary according to the particular localization method being used. The resulting set of received NMR signals, or k-space (e.g., frequency domain) samples, are digitized and processed to reconstruct the image using known reconstruction techniques.

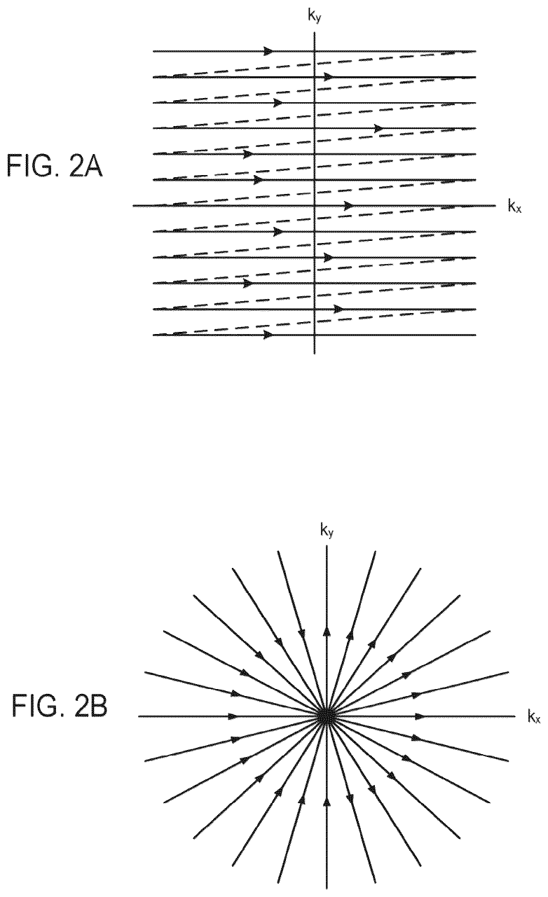

Most commonly, when the k-space data is acquired using Cartesian sampling, the reconstruction of the data from k-space to the image space is achieved using a Fourier transform or any of a variety of reconstruction techniques that utilize a Fourier transform. Such a k-space sampling is illustrated in FIG. 2A. There are many, many variations on techniques for using the Fourier transform as part of a reconstruction process for k-space data sampled using a Cartesian or similar sampling strategy.

Projection reconstruction methods have been known since the inception of magnetic resonance imaging. Rather than sampling k-space in a rectilinear, or Cartesian, scan pattern as is done in Fourier imaging and shown in FIG. 2A, projection reconstruction methods sample k-space data with a series of views that sample radial lines extending outward from the center of k-space as shown in FIG. 2B. The number of views needed to sample k-space determines the length of the scan and if an insufficient number of views are acquired, streak artifacts are produced in the reconstructed image.

In MRI the most common method is to re-grid the k-space samples (e.g., NMR data) from their locations on the radial sampling trajectories to a Cartesian grid. The image is then reconstructed by performing a 2D or 3D Fourier transformation of the re-gridded k-space samples. The second method for reconstructing an MR image is to transform the radial k-space projection views to Radon space by first Fourier transforming each projection view. An image is reconstructed from these signal projections by filtering and back projecting them into the field of view. As is well known in the art, if the acquired signal projections are insufficient in number to satisfy the Nyquist sampling theorem, streak artifacts are produced in the reconstructed image.

Depending on the technique used, many MR scans currently used to produce medical images require many minutes to acquire the necessary data. The reduction of this scan time is an important consideration, since reduced scan time increases patient throughout, improves patient comfort, and improves image quality by reducing motion artifacts. Many different strategies have been developed to shorten the scan time.

One such strategy is referred to generally as “parallel imaging”. Parallel imaging techniques use spatial information from arrays of RF receiver coils to substitute for the encoding that would otherwise have to be obtained in a sequential fashion using RF pulses and field gradients (such as phase and frequency encoding). Each of the spatially independent receiver coils of the array carries certain spatial information and has a different sensitivity profile. This information is utilized in order to achieve a complete location encoding of the received MR signals by a combination of the simultaneously acquired data received from the separate coils. Specifically, parallel imaging techniques under sample k-space by reducing the number of acquired phase-encoded k-space sampling lines while keeping the maximal extent covered in k-space fixed. The combination of the separate MR signals produced by the separate receiver coils enables a reduction of the acquisition time required for an image (in comparison to conventional k-space data acquisition) by a factor that in the most favorable case equals the number of the receiver coils. Thus, the use of multiple receiver coils acts to multiply imaging speed, without increasing gradient switching rates or RF power.

Two categories of such parallel imaging techniques that have been developed and applied to in vivo imaging are SENSE (SENSitivity Encoding) and SMASH (SiMultaneous Acquisition of Spatial Harmonics). With SENSE, the under sampled k-space data is first Fourier transformed to produce an aliased image from each coil, and then the aliased image signals are unfolded by a linear transformation of the superimposed pixel values. With SMASH, the omitted k-space lines are filled in or reconstructed prior to Fourier transformation, by constructing a weighted combination of neighboring lines acquired by the different receiver coils. SMASH requires that the spatial sensitivity of the coils be determined, and one way to do so is by “autocalibration” that entails the use of variable density k-space sampling.

The data acquisition methods are significantly different in the above exemplary imaging modalities. Namely, k-space is sampled to measure Fourier coefficients in MR data acquisitions, while line integrals are measured in x-ray CT data acquisitions. Despite this, the challenge in image reconstruction for both modalities, as well as many other imaging modalities, is common: reconstructing a high-quality image.

According to standard image reconstruction theories, in order to reconstruct an image without aliasing artifacts, the sampling rate employed to acquire image data must satisfy the so-called Nyquist criterion, which is set forth in the Nyquist-Shannon sampling theorem. Moreover, in standard image reconstruction theories, no specific prior information about the image is needed. On the other hand, when some prior information about the desired or target image is available and appropriately incorporated into the image reconstruction procedure, an image can be accurately reconstructed even if the Nyquist criterion is violated. For example, if one knows a desired, target image is circularly symmetric and spatially uniform, only one view of parallel-beam projections (i.e., one projection view) is needed to accurately reconstruct the linear attenuation coefficient of the object. As another example, if one knows that a desired, target image consists of only a single point, then only two orthogonal projections that intersect at said point are needed to accurately reconstruct the image point. Thus, if prior information is known about the desired target image, such as if the desired target image is a set of sparsely distributed points, it can be reconstructed from a set of data that was acquired in a manner that does not satisfy the Nyquist criterion. Put more generally, knowledge about the sparsity of the desired target image can be employed to relax the Nyquist criterion; however, it is a highly nontrivial task to generalize these arguments to formulate a rigorous image reconstruction theory.

The Nyquist criterion serves as one of the paramount foundations of the field of information science. However, it also plays a pivotal role in modern medical imaging modalities such as MRI and x-ray CT imaging. When the number of data samples acquired by an imaging system is less than the requirement imposed by the Nyquist criterion, artifacts appear in the reconstructed images. In general, such image artifacts include aliasing and streaking artifacts. In practice, the Nyquist criterion is often violated, whether intentionally or through unavoidable circumstances. For example, in order to shorten the data acquisition time in a time-resolved MR angiography study, under sampled projection reconstruction, or radial, acquisition methods are often intentionally introduced.

In contrast, under sampling is inevitable in four-dimensional cone beam CT (4D CBCT), such as when utilized in image-guided radiation therapy (IGRT). For example, in the case of IGRT, cone beam projection data are acquired over 10-15 respiratory cycles during a 60 second gantry rotation time. The acquired data is then retrospectively gated into 8-10 phases by synchronizing the respiratory signals with the data acquisition. After the respiratory gating, less than 100 cone beam projections are typically available to reconstruct images for each respiratory phase. Consequently, streaking artifacts are rampant in the reconstructed images for each respiratory phase. These under sampling artifacts pose a major challenge in 4D CBCT and limit the use of 4D CBCT in clinical practice.

Some image reconstruction methods have attempted to use prior or other information to overcome challenges to producing high-quality images. For example, one method called highly constrained back projection (HYPR) has been developed in which quality images can be reconstructed from far fewer projection signal profiles when a priori knowledge of the signal information is used in the reconstruction process. For example, signal information in an angiographic study may be known to include structures such as blood vessels. That being the case, when a back projection path passes through these structures a more accurate distribution of a signal sample in each pixel can be achieved by weighting the distribution as a function of the known signal information at that pixel location. In HYPR, for a back projection path having N pixels the highly constrained back projection may be expressed as follows:

$${S}_{n} = \frac{( P \times {C}_{n} )}{{\sum }_{n = 1}^{N} {C}_{n}}$$

In the above equation, S, is the back projected signal magnitude at a pixel n in an image frame being reconstructed, P is the signal sample value in the projection profile being back projected, and Cₙ is the signal value of an a priori composite image at the n^{th} pixel along the back projection path. The composite image is reconstructed from data acquired during the scan, and may include that used to reconstruct the given image frame as well as other acquired image data that depicts the structures in the field of view. The numerator in the equation above, (P×Cₙ), weights each pixel using the corresponding signal value in the composite image and the denominator,

$${\sum }_{n = 1}^{N} {C}_{n} ,$$

normalizes the value so that all back projected signal samples reflect the projection sums for the image frame and are not multiplied by the sum of the composite image.

Regardless of the imaging modality or the data type acquired, all reconstruction techniques are fundamentally based on a few principles. First, a known data sampling is performed to yield a set of data of known characteristics. Then, based on the known data sampling technique and the known characteristics of the data set, an appropriate reconstruction technique is applied that will transform the raw set of data into an image. Thus, a known reconstruction technique matched to the underlying data is applied that serves to transform the raw data from a first domain in which it was acquired to a second domain where it can be understood as an image.

For example, in CT, the data is acquired as Hounsfield units that are transformed using filtered back projection or another technique into pixels with associated contrast values in an image. In MR, the data is acquired as k-space or frequency domain data that is transformed using, typically a type of Fourier transform, into the image domain (e.g., a spatial domain in which the arrangement and relationship among different pixel values are expressed) to generate an image. Other imaging modalities follow this exact or similar process. For example, PET imaging uses the filtered back projection technique.

Despite the success of this paradigm in medical and non-medical imaging applications, they suffer from regular and extensive shortcomings. Case in point, the Nyquist criterion is a fundamental tenant of imaging that, when not observed, often requires extensive efforts to buttress the applicable reconstruction technique with additional compensations to overcome the fact that the resulting images, without such compensation, would suffer from artifacts that reduce the value of the images. Thus, in the patent literature alone, there are thousands of examples of small changes, additions, or variations on the fundamental reconstruction techniques.

The present disclosure provides in some aspects systems, methods, and media that can transform raw data into an image and, thereby, serve as a reconstruction technique, but without the need for the reconstruction technique being predesigned to compensate for anticipated data acquisition characteristics, including shortcomings in the data (such as under sampling). Furthermore, the present disclosure provides in some aspects systems, methods, and media that can provide feedback that informs the data acquisition techniques that can be used in the future. That is, the reconstruction process is not dictated by the data acquisition process, but rather data reconstruction can be performed irrespective of data acquisition and, instead, serve to inform future data acquisitions to further improve reconstructed images.

The present disclosure also provides in some aspects systems, methods, and media for transforming data sets acquired in a first domain into a data set in a second domain using aggregated preferred results in the second domain as a guide for informing the domain transform or reconstruction process. This stands in contrast to traditional domain transform or reconstruction techniques that dictate the way in which the data must be acquired in the first domain so that the domain transform or reconstruction technique can deliver results in the second domain that are desirable. That is, in the case of projections acquired through k-space in Mill, one typically re-grids the data to allow a Fourier transform to be performed. In this way, the preconception of the data by the reconstruction technique necessitates that the data be presented (in both form and substance—such as sampling density) in a predetermined manner that will yield desirable images when transformed to the image domain. The systems, methods, and media described herein may not be limited in this manner. A framework is provided that can be leveraged to create images or transform data from one domain to another without a preconceived constraint on the data acquired or to be acquired.

For example, a data-driven manifold learning construct can be used as a generalized image reconstruction technique to transform raw sensor to another domain or, in the case of imaging, transform image data into images, without human-devised, acquisition-specific mathematical transforms. In a non-limiting context, this construct or framework may be referred to herein as AUTOMAP (AUtomated TransfOrm by Manifold Approximation) or in some cases as a deep reconstruction network (DRN).

By not constraining the image reconstruction or domain transfer problem to human-devised, acquisition-specific transforms, new signal domains beyond conventional representations (e.g., k-space/Fourier space, O-space, Radon, etc.) can be used acquire data. Reinforcement learning can be used to automatically program novel methods for data acquisition. As one non-limiting example, AUTOMAP can be used to design new pulse sequences for MM. Likewise, the data acquisition itself need not be constrained to known domains. The automated acquisition and automated reconstruction stages can be trained in tandem to produce optimal imaging protocols and resultant images.

Accordingly, the systems, methods, and media described herein can be used in any of a variety of setting where one looks to transform data from one domain to another domain and/or develop and devise data acquisition strategies that yield improved results by analyzing the desired ends to the data acquisition. For example, beyond the non-limiting examples provided herein, the systems and methods of the present disclosure can be extended to other imaging modalities, such as optical (e.g., optical coherence tomography, speckle imaging, and the like) and even non-imaging applications, such as general data processing.

Moreover, the systems, methods, and media described herein are not limited to applications where a domain transform is necessary or advantageous to yield an image or improved image. This and other points will be made clear with respect to the following description. However, before turning to some more specific aspects of the present disclosure, some non-limiting examples of operational environments in which aspects of the present disclosure can be implemented (e.g., imaging systems) are provided.

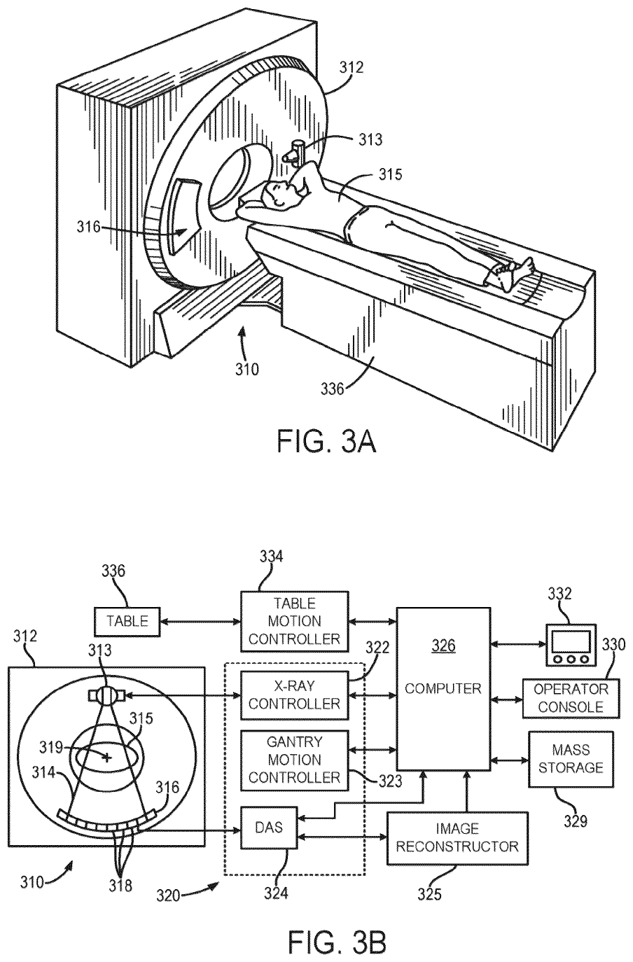

Referring to FIG. 3A and FIG. 3B, specifically, an x-ray computed tomography (CT) imaging system 310 is shown that includes a gantry 312 representative of a “third generation” CT scanner. Gantry 312 has an x-ray source 313 that projects a fan beam, or cone beam, of x-rays 314 toward a detector array 316 on the opposite side of the gantry. The detector array 316 is formed by a number of detector elements 318 which together sense the projected x-rays that pass through a medical patient 315. Each detector element 318 produces an electrical signal that represents the intensity of an impinging x-ray beam and hence the attenuation of the beam as it passes through the patient. As will be described, this acquired attenuation data of a CT system 310 can be referred to as “sensor data”. In the case of CT imaging, such data is typically in Radon space and measured in Hounsfield units. In this way, such sensor data can be referred to as being acquired in a “sensor domain”. In the case of CT imaging and its respective sensor domain, the sensor data must be transformed to an image domain, such as by using filtered back projection, to yield a reconstructed image. However, as will be described, constraining reconstruction or acquisition based on such traditional tools for domain transfer and their inherent limitations is not necessary. Thus, as will be explained, breaking from this traditional paradigm of CT image reconstruction can yield, in accordance with the present disclosure, superior images.

During a scan to acquire x-ray projection data, the gantry 312 and the components mounted thereon rotate about a center of rotation 319 located within the patient 315. The rotation of the gantry and the operation of the x-ray source 313 are governed by a control mechanism 320 of the CT system. The control mechanism 320 includes an x-ray controller 322 that provides power and timing signals to the x-ray source 313 and a gantry motor controller 323 that controls the rotational speed and position of the gantry 312. A data acquisition system (DAS) 324 in the control mechanism 320 samples analog data from detector elements 318 and converts the data to digital signals for subsequent processing. An image reconstructor 325, receives sampled and digitized x-ray data from the DAS 324 and performs high speed image reconstruction. The reconstructed image is applied as an input to a computer 326 which stores the image in a mass storage device 328.

The computer 326 also receives commands and scanning parameters from an operator via console 330 that has a keyboard. An associated display 332 allows the operator to observe the reconstructed image and other data from the computer 326. The operator supplied commands and parameters are used by the computer 326 to provide control signals and information to the DAS 324, the x-ray controller 322 and the gantry motor controller 323. In addition, computer 326 operates a table motor controller 334 which controls a motorized table 336 to position the patient 315 in the gantry 312.

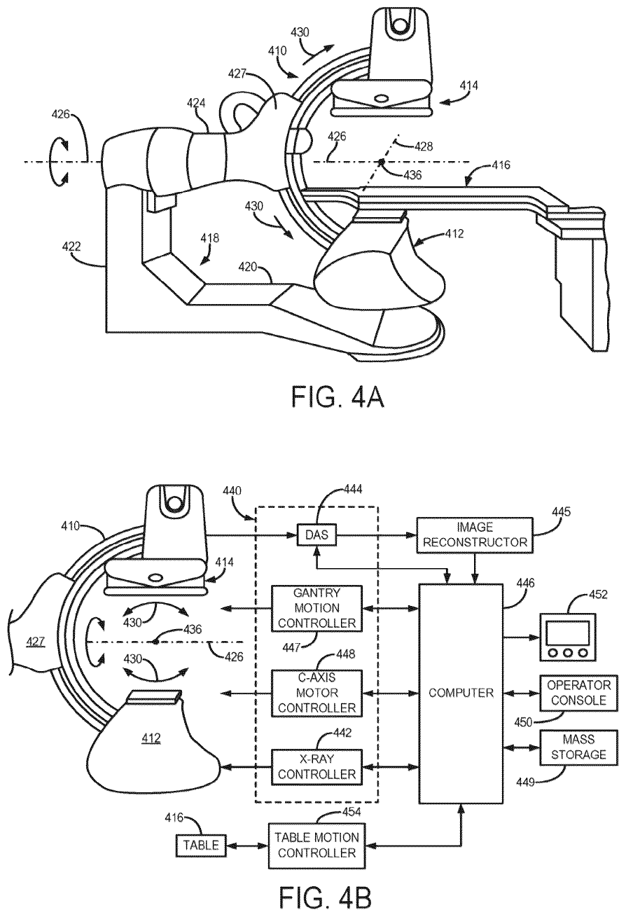

Referring to FIG. 4A and FIG. 4B, an example x-ray system is shown that is designed for use in connection with interventional procedures. It is characterized by a gantry having a C-arm 410 which carries an x-ray source assembly 412 on one of its ends and an x-ray detector array assembly 414 at its other end. Similar to the above-described CT system 310, the data acquired by the C-arm system illustrated in FIGS. 4A and 4B can be referred to as “sensor data”, in this case, typically, acquired in Radon space and measured in Hounsfield units. Again, such sensor data must be transformed to an image domain, such as by using filtered back projection, to yield a reconstructed image.

The gantry enables the x-ray source 412 and detector 414 to be oriented in different positions and angles around a patient disposed on a table 416, while enabling a physician access to the patient. The gantry includes an L-shaped pedestal 418 which has a horizontal leg 420 that extends beneath the table 416 and a vertical leg 422 that extends upward at the end of the horizontal leg 420 that is spaced from of the table 416. A support arm 424 is rotatably fastened to the upper end of vertical leg 422 for rotation about a horizontal pivot axis 426. The pivot axis 426 is aligned with the centerline of the table 416 and the arm 424 extends radially outward from the pivot axis 426 to support a C-arm drive assembly 427 on its outer end. The C-arm 410 is slidably fastened to the drive assembly 427 and can be coupled to a drive motor which slides the C-arm 410 to revolve it about a C-axis 428 as indicated by arrows 430. The pivot axis 426 and C-axis 428 intersect each other at an isocenter 436 located above the table 416 and they are perpendicular to each other.

The x-ray source assembly 412 is mounted to one end of the C-arm 410 and the detector array assembly 414 is mounted to its other end. As will be discussed in more detail below, the x-ray source 412 emits a cone beam of x-rays which are directed at the detector array 414. Both assemblies 412 and 414 extend radially inward to the pivot axis 426 such that the center ray of this cone beam passes through the system isocenter 436. The center ray of the cone beam can thus be rotated about the system isocenter around either the pivot axis 426 or the C-axis 428, or both during the acquisition of x-ray attenuation data from a subject placed on the table 416.

Referring particularly to FIG. 4B, the rotation of the assemblies 412 and 414 and the operation of the x-ray source 432 are governed by a control mechanism 440 of the CT system. The control mechanism 440 includes an x-ray controller 442 that provides power and timing signals to the x-ray source 432. A data acquisition system (DAS) 444 in the control mechanism 440 samples data from detector elements 438 and passes the data to an image reconstructor 445. The image reconstructor 445, receives digitized x-ray data from the DAS 444 and performs high speed image reconstruction according to the methods of the present invention. The reconstructed image is applied as an input to a computer 446 which stores the image in a mass storage device 449 or processes the image further.

The control mechanism 440 also includes pivot motor controller 447 and a C-axis motor controller 448. In response to motion commands from the computer 446 the motor controllers 447 and 448 provide power to motors in the x-ray system that produce the rotations about respective pivot axis 426 and C-axis 428. A program executed by the computer 446 generates motion commands to the motor drives 447 and 448 to move the assemblies 412 and 414 in a prescribed scan path.

The computer 446 also receives commands and scanning parameters from an operator via console 450 that has a keyboard and other manually operable controls. An associated cathode ray tube display 452 allows the operator to observe the reconstructed image and other data from the computer 446. The operator supplied commands are used by the computer 446 under the direction of stored programs to provide control signals and information to the DAS 444, the x-ray controller 442 and the motor controllers 447 and 448. In addition, computer 446 operates a table motor controller 454 which controls the motorized table 416 to position the patient with respect to the system isocenter 436.

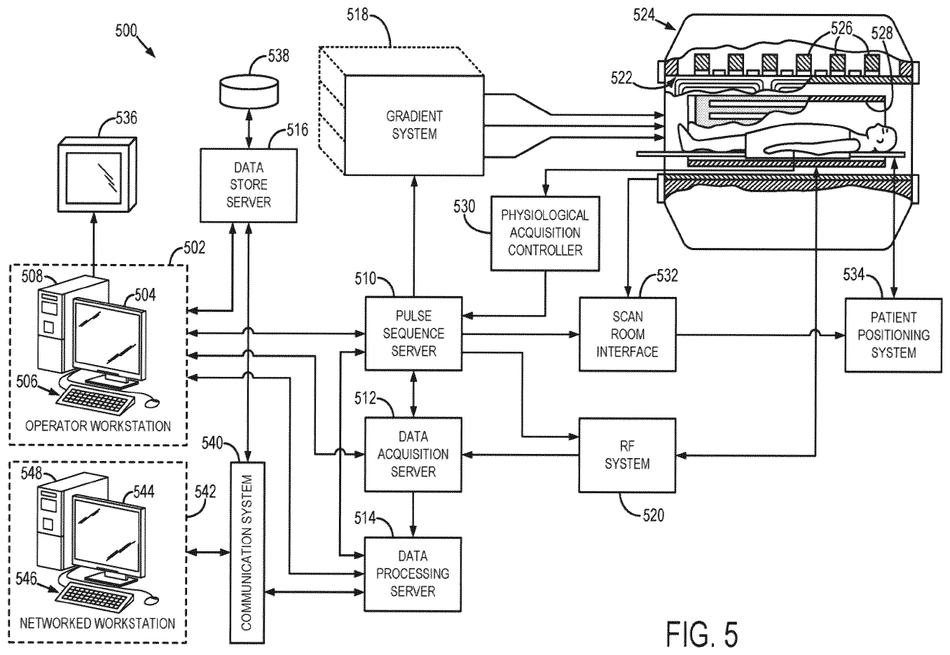

Referring to FIG. 5, an example of an Mill system 500 is illustrated. The MM system 500 includes a workstation 502 having a display 504 and a keyboard 506. The workstation 502 includes a processor 508 that is commercially available to run a commercially available operating system. The workstation 502 provides the operator interface that enables scan prescriptions to be entered into the Mill system 500. The workstation 502 is coupled to four servers: a pulse sequence server 510; a data acquisition server 512; a data processing server 514; and a data store server 516. The workstation 502 and each of the servers 510, 512, 514, and 516 are communicatively connected to communicate with each other.

The pulse sequence server 510 functions in response to instructions downloaded from the workstation 502 to operate a gradient system 518 and a radiofrequency (RF) system 520. Gradient waveforms necessary to perform the prescribed scan are produced and applied to the gradient system 518, which excites gradient coils in an assembly 522 to produce the magnetic field gradients Gₓ, G_{y}, and G_{z} used for position encoding MR signals. The gradient coil assembly 522 forms part of a magnet assembly 524 that includes a polarizing magnet 126 and a whole-body RF coil 528 and/or local coil.

RF excitation waveforms are applied to the RF coil 528, or a separate local coil, such as a head coil, by the RF system 520 to perform the prescribed magnetic resonance pulse sequence. Responsive MR signals detected by the RF coil 528, or a separate local coil, are received by the RF system 520, amplified, demodulated, filtered, and digitized under direction of commands produced by the pulse sequence server 510. The RF system 520 includes an RF transmitter for producing a wide variety of RF pulses used in MR pulse sequences. The RF transmitter is responsive to the scan prescription and direction from the pulse sequence server 510 to produce RF pulses of the desired frequency, phase, and pulse amplitude waveform. The generated RF pulses may be applied to the whole-body RF coil 528 or to one or more local coils or coil arrays.

The RF system 520 also includes one or more RF receiver channels. Each RF receiver channel includes an RF preamplifier that amplifies the MR signal received by the coil 528 to which it is connected, and a detector that detects and digitizes the quadrature components of the received MR signal. The magnitude of the received MR signal may thus be determined at any sampled point by the square root of the sum of the squares of the I and Q components:

M=\sqrt{I²+Q²}

Also, the phase of the received MR signal may also be determined using the equation:

$$φ = {tan}^{- 1} ( \frac{Q}{I} )$$

In the case of an MRI system 500, these acquired RF signals are sampled in “k-space”, which is a frequency domain. Thus, the MRI system 500 acquires “sensor data” in the frequency domain, which represents the “sensor domain” for MR or NMR imaging. Such MR sensor data can then be transformed to an image domain to yield a reconstructed image, which can be achieved via a Fourier transform or projection reconstruction technique. However, as will be described, constraining reconstruction or acquisition based on such tools for domain transfer and their inherent limitations may not be necessary. Thus, breaking from this traditional paradigm of MR image reconstruction can yield superior images.

The pulse sequence server 510 also optionally receives patient data from a physiological acquisition controller 530. The controller 530 receives signals from a number of different sensors connected to the subject to be scanned, such as electrocardiograph (ECG) signals from electrodes, or respiratory signals from a bellows or other respiratory monitoring device. Such signals are typically used by the pulse sequence server 510 to synchronize, or “gate”, the performance of the scan with the subject's heartbeat or respiration. The pulse sequence server 510 also connects to a scan room interface circuit 532 that receives signals from various sensors associated with the condition of the patient and the magnet system. A patient positioning system 532 may be included.

The digitized MR signal samples produced by the RF system 520 are received by the data acquisition server 512. The data acquisition server 512 operates in response to instructions downloaded from the workstation 502 to receive the real-time MR data and provide buffer storage, such that no data is lost by data overrun. In some scans, the data acquisition server 512 does little more than pass the acquired MR data to the data processor server 514. However, in scans that require information derived from acquired MR data to control the further performance of the scan, the data acquisition server 512 is programmed to produce such information and convey it to the pulse sequence server 510. For example, during pre-scans, MR data is acquired and used to calibrate the pulse sequence performed by the pulse sequence server 510. Also, navigator signals may be acquired during a scan and used to adjust the operating parameters of the RF system 520 or the gradient system 518, or to control the view order in which k-space data (e.g., frequency domain data) is sampled. In all these examples, the data acquisition server 512 acquires MR data and processes it in real-time to produce information that is used to control the scan.

The data processing server 514 receives MR data from the data acquisition server 512 and processes it in accordance with instructions downloaded from the workstation 502. Such processing may include, for example: Fourier transformation of raw k-space MR data to produce two or three-dimensional images; the application of filters to a reconstructed image; the performance of a back projection image reconstruction of acquired MR data; the generation of functional MR images; and the calculation of motion or flow images.

Images reconstructed by the data processing server 514 are conveyed back to the workstation 502 where they are stored. Real-time images are stored in a data base memory cache, from which they may be output to operator display 504 or a display 536 that is located near the magnet assembly 524 for use by attending physicians. Batch mode images or selected real time images are stored in a host database on disc storage 538. When such images have been reconstructed and transferred to storage, the data processing server 514 notifies the data store server 516 on the workstation 502. The workstation 502 may be used by an operator to archive the images, produce films, or send the images via a network or communication system 540 to other facilities that may include other networked workstations 542.

The communication system 540 and networked workstation 542 may represent any of the variety of local and remote computer systems that may be included within a given imaging facility including the system 500 or other, remote location that can communicate with the system 500. In this regard, the networked workstation 542 may be functionally and capably similar or equivalent to the operator workstation 502, despite being located remotely and communicating over the communication system 540. As such, the networked workstation 542 may have a display 544 and a keyboard 546. The networked workstation 542 includes a processor 548 that is commercially available to run a commercially available operating system. The networked workstation 542 may be able to provide the operator interface that enables scan prescriptions to be entered into the MRI system 500.

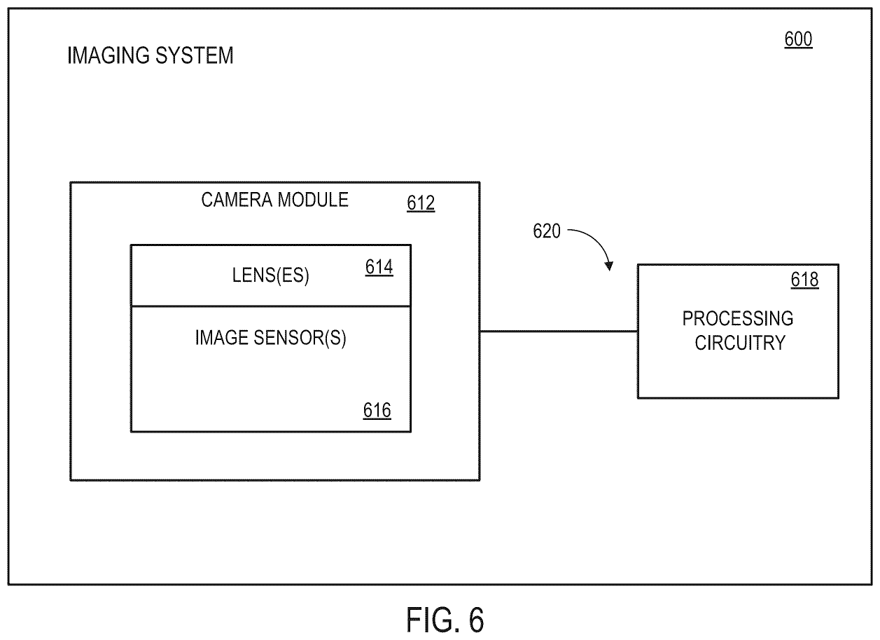

FIG. 6 shows an example imaging system 600 that uses one or more image sensors to capture images and that includes processing circuitry configured to execute an AUTOMAP image reconstruction algorithm such as detailed further below. The imaging system 600 may be a portable imaging system such as a camera, a cellular telephone, a video camera, or any other imaging device that captures digital image data. A camera module 612 may be used to convert incoming light into digital image data. The camera module 612 includes one or more lenses 614 and one or more corresponding image sensors 616. In some embodiments, the lens 614 may be part of an array of lenses and image sensor 616 may be part of an image sensor array.

Processing circuitry 618 may include one or more integrated circuits (e.g., image processing circuits, microprocessors, storage devices such as random-access memory and non-volatile memory, etc.) and may be connected via in input 620 to the camera module 612 and/or that form part of the camera module 612 (e.g., circuits that form part of an integrated circuit that includes the image sensor 616 or an integrated circuit within the camera module 612 that is associated with the image sensor 616). Image data that has been captured and processed by the camera module 612 may, if desired, be further processed and stored using the processing circuitry 618. Processed image data may, if desired, be provided to external equipment, such as a computer or other electronic device, using wired and/or wireless communication paths coupled to the processing circuitry 618. For example, the processing circuitry 618 may include a field programmable gate array (FPGA) or an application specific integrated circuit (ASIC), with which the AUTOMAP data-driven manifold learning processes may be performed in order to execute generalized image reconstruction techniques to transform raw data (e.g., pixel voltages) generated by the image sensor 616 into images in the image domain (e.g., a spatial domain in which the arrangement and relationship among different pixel values are expressed) without the use of human-devised acquisition-specific mathematical functions.

For example, an array of photo-sensitive pixels within the image sensor 616 may generate an array of pixel voltages corresponding to a captured image when exposed to light. This array of pixel voltages may be transformed into visual representations of the captured image in the image domain using a learned (e.g., trained) AUTOMAP image reconstruction process executed by the processing circuitry 618. For example, a neural network may be used to transform digital voltages output by analog-to-digital converter (ADC) circuitry (e.g., that processes the outputs of the pixels of the image sensor 616) to the image domain.

Digital photography and cinematography performed in low-light conditions may result in low-quality images and videos due to image sensor non-idealities (e.g., thermal noise of CCD and CMOS image sensors or read-out noise of on-chip amplifiers in the image sensor) when using traditional image processing techniques. By using learned AUTOMAP image reconstruction in place of traditional image processing techniques, image sensor defects may be automatically compensated for and, because learned image reconstruction may be robust to corruptive channel noise such as additive white Gaussian noise, signal-to-noise ratio (SNR) for the image may be comparatively improved, especially when the learned image reconstruction is trained using real-world representative data (images).

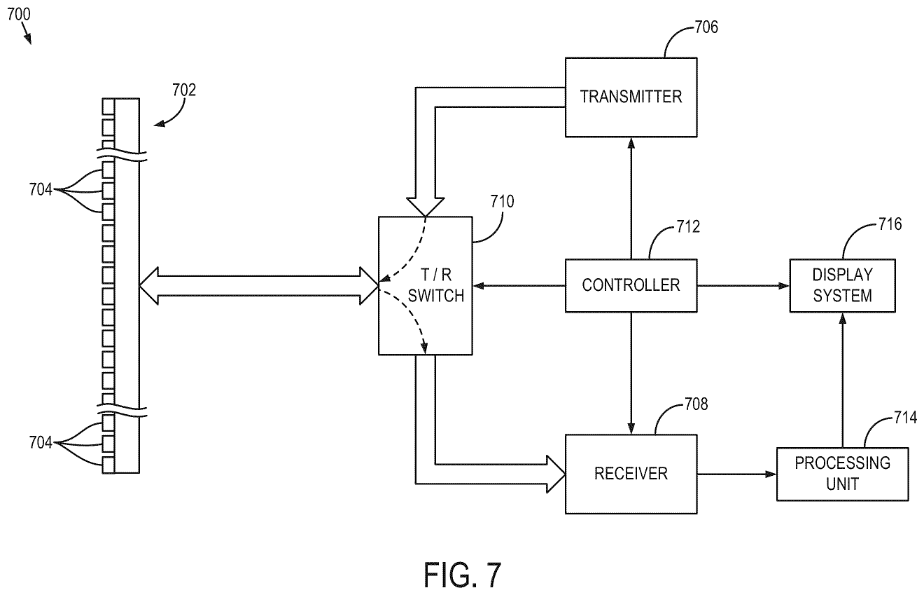

FIG. 7 shows an example ultrasound system 700 that can implement the methods described in the present disclosure. The ultrasound system 700 includes a transducer array 702 that includes a plurality of separately driven transducer elements 704. The transducer array 702 can include any suitable ultrasound transducer array, including linear arrays, curved arrays, phased arrays, and so on. Similarly, the transducer array 702 can include a 1D transducer, a 1.5D transducer, a 1.75D transducer, a 2D transducer, a 3D transducer, and so on.

When energized by a transmitter 706, a given transducer element 704 produces a burst of ultrasonic energy. The ultrasonic energy reflected back to the transducer array 702 (e.g., an echo) from the object or subject under study is converted to an electrical signal (e.g., an echo signal) by each transducer element 704 and can be applied separately to a receiver 708 through a set of switches 710. The transmitter 706, receiver 708, and switches 710 are operated under the control of a controller 712, which may include one or more processors. As one example, the controller 712 can include a computer system.

The transmitter 706 can be programmed to transmit unfocused or focused ultrasound waves. In some configurations, the transmitter 706 can also be programmed to transmit diverged waves, spherical waves, cylindrical waves, plane waves, or combinations thereof. Furthermore, the transmitter 706 can be programmed to transmit spatially or temporally encoded pulses. The receiver 708 can be programmed to implement a suitable detection sequence for the imaging task at hand. In some embodiments, the detection sequence can include one or more of line-by-line scanning, compounding plane wave imaging, synthetic aperture imaging, and compounding diverging beam imaging.

In some configurations, the transmitter 706 and the receiver 708 can be programmed to implement a high frame rate. For instance, a frame rate associated with an acquisition pulse repetition frequency (“PRF”) of at least 100 Hz can be implemented. In some configurations, the ultrasound system 700 can sample and store at least one hundred ensembles of echo signals in the temporal direction. The controller 712 can be programmed to design an imaging sequence. In some examples, the controller 712 receives user inputs defining various factors used in the design of the imaging sequence.

A scan can be performed by setting the switches 710 to their transmit position, thereby directing the transmitter 706 to be turned on momentarily to energize transducer elements 704 during a single transmission event according to the designed imaging sequence. The switches 710 can then be set to their receive position and the subsequent echo signals produced by the transducer elements 704 in response to one or more detected echoes are measured and applied to the receiver 708. The separate echo signals from the transducer elements 704 can be combined in the receiver 708 to produce a single echo signal. The echo signals are communicated to a processing unit 714, which may be implemented by a hardware processor and memory, to process echo signals or images generated from echo signals. As an example, the processing unit 714 can implement AUTOMAP image reconstruction, including realizing a neural network (e.g., the models 900, 1000, 1300 detailed below) for transforming the echo signals (e.g., raw data in the sensor domain in which the ultrasound system 700 operates) into a visual representation (e.g., an image in the image domain) of the object or subject under study, or of a portion thereof, using the methods described in the present disclosure. Images produced from the echo signals by the processing unit 714 can be displayed on a display system 716.

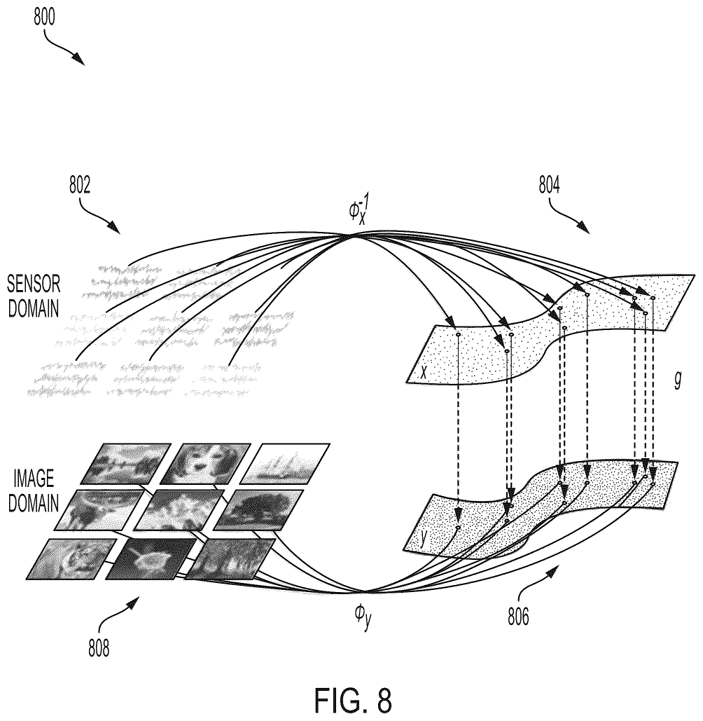

FIG. 8 shows a flow diagram illustrating an example process 800 for image reconstruction between a sensor domain and an image domain using a data-driven, manifold learning approach (e.g., using neural networks). Sensor data 802 may be generated when an image is captured using any one of a variety of imaging systems including, but not limited to, a magnetic resonance imaging (Mill) system, a computed tomography (CT) scanning system, a positron emission tomography (PET) scanning system, an ultrasound system, an optical complementary metal oxide semiconductor (CMOS) imaging system, and an optical charge coupled device (CCD) image sensor. Sensor data 802 may be acquired or encoded in a particular domain corresponding to the particular method of image capture used to acquire/generate the sensor data 802, which can be referred to herein as the “sensor domain”. Any noise that may be present within the sensor data 802 (e.g., as a result of non-idealities involved with image capture) is inherently intertwined with the sensor data. As noted, the sensor data 802 may be encoded in one of a variety of different domains (e.g., frequency domain, Radon domain, etc.) depending on the method of data acquisition used, the domain of any given set of sensor data may be referred to herein generally as the sensor domain. By transforming the sensor data 802 from the sensor domain to the image domain to produce image data 808, the sensor data 802 may be effectively decoded.

In FIG. 8, x represents the sensor data 802 in the sensor domain, and y represents image data 808 in the image domain. Given \tilde{x}, the noisy observation of sensor domain data x, the stochastic projection operator onto X: p(\tilde{x})=P(x|\tilde{x}) may be learned. After obtaining X, the second task is to reconstruct f(x) by producing a reconstruction mapping \hat{f} [symbol] n²→ [symbol] n² that minimizes the reconstruction error L(\hat{f}(x), f (x)).

With this starting context, the reconstruction process can be described for an idealized scenario, for example, where the input sensor data are noiseless. Denote the data as (yᵢ,xᵢ)ᵢ₌₁ⁿ where for i^{th} observation xᵢ indicates a n×n set of input parameters, and yᵢ indicates the n×n real, underlying images. It may be assumed:
1) That there exists an unknown smooth and homeomorphic function f: [symbol] n²→ [symbol] n² such that y=f (x), and
2) That (xᵢ)ᵢ₌₁ⁿ, (yᵢ)ᵢ₌₁ⁿ lie on unknown smooth manifolds χ and [symbol] (e.g., manifolds 804 and 806), respectively.

Both manifolds 804 and 806 are embedded in the ambient space [symbol] n², such that dim (χ)<n² and dim ( [symbol] )<n². The above two assumptions combine to define a joint manifold [symbol] =χ× [symbol] that the dataset (xᵢ, yᵢ)ᵢ₌₁ⁿ lies in, which can be written as:

[symbol]

={(x,f(x))∈ [symbol] n²× [symbol] n²|x∈χ,f(x)∈ [symbol] }

Note that (x, f (x)) is described using the regular Euclidean coordinate system. However, we may equivalently describe this point using the intrinsic coordinate system of [symbol] as (z, g(z)) such that there exists a homeomorphic mapping ϕ=(ϕₓ, ϕ_{y}) between (x, f (x)) and (z, g(z)). (i.e., x=ϕₓ(z) and f(x)=ϕ_{y}ºg(z)). As a side note, in topology, ϕ=(ϕₓ, ϕ_{y}): [symbol] → [symbol] n² × [symbol] n² may correspond to the local coordinate chart of [symbol] at the neighborhood of (x, f (x)). Instead of directly learning f in the ambient space, it may be desirable to learn the diffeomorphism g between χ and [symbol] in order to take advantage of the low-dimensional nature of embedded space. Consequently, the process of generating y=f (x) from x can be written as a sequence of function evaluations:

f(x)=ϕ_{y}ºgºϕₓ⁻¹(x)

For the convenience of later presentation, notice that given input image x, the output image follows a probability distribution Q(Y|X=x, f), which is a degenerate distribution with point mass at y=f (x).

With the context provided by this idealized sensor data that is free of noise in place, a non-ideal scenario, where noise or other corruption exists in the sensor domain input and a corresponding de-noising process, are now described. Instead of observing the perfect input data xᵢ, \tilde{x}ᵢ is observed, which is sensor data with noise or a corrupted version of xᵢ by some known noise or corruption process described by the probability distribution P(\tilde{X}|X=x). In order to handle this complication, a denoising step Q(X|\tilde{X}=\tilde{x}, p) may be used to our model pipeline, such that our prediction for y is no longer a deterministic value, but a random variable with conditional distribution P(Y|\tilde{X}) so that the prediction uncertainty caused by the corruption process may be properly characterized.

Instead of learning this denoising step explicitly, an analogy may be drawn from denoising autoencoders. The joint distribution P(Y, X, \tilde{X}) may be modeled instead. Specifically, in addition to the assumptions (1)-(2) listed above, also assume:
3) That the true distribution P(X|\tilde{X}) lies in the semiparametric family [symbol] defined by its first moment [symbol] ={Q(X|\tilde{X}=\tilde{x}, p)|E(X)=p(\tilde{X})}.

P(Y, X, \tilde{X}) may be modeled using the decomposition below:

Q_{(f,p)}(Y,X,\tilde{X})=Q(Y|X,f)Q(X|\tilde{X},p)P(\tilde{X})

In this decomposition, Q (Y|X, f) denotes the model for reconstruction process described above, Q (X|\tilde{X}, p) denotes the de-noising operator, and P(\tilde{X}) denotes the empirical distribution of corrupted images. Notice that the models for de-noising and reconstruction processes may be combined together by collapsing the first two terms on the right-hand side into one term, which gives:

Q_{(f,p)}(Y,X,\tilde{X})=Q(Y,X|\tilde{X},(f,p))P(\tilde{X})

It should be noted that Y=f(X) is a deterministic and homeomorphic mapping of X; therefore, Q(Y, X|\tilde{X}, (f, p))=Q(Y|\tilde{X}, (f,p)) is the predictive distribution of output image y given the noisy input \tilde{x}, which is the estimator of interest. Consequently, the model can be written as:

Q_{(f,p)}(Y,X,\tilde{X})=Q(Y|\tilde{X},(f,p))P(\tilde{X})

This then represents a definition of the model for the joint distribution. In the actual training stage, “perfect” (e.g., substantially noiseless) input images x are available, and the model can be trained with \tilde{x} that is generated from P(\tilde{X}|X=x). That is to say, the joint distribution of (Y, X, \tilde{X}) observed in training data admits the form:

P(Y,X,\tilde{X})=P(Y|X)P(\tilde{X}|X)P(X)

The training can proceed by minimizing the KL-divergence between observed probability P(Y, X, \tilde{X}) and the model Q(Y, X, \tilde{X}),

[symbol]

_{KL}{P(Y,X,\tilde{X})∥Q_{(f,p)}(Y,X,\tilde{X})}

with respect to the function-valued parameters (f, p). As the KL-divergence converges toward 0, Q(X|\tilde{X}, p) converges to P(X|\tilde{X}), the de-noising projection, and at the same time Q(Y|\tilde{X},(f,p)) converges to P(Y|\tilde{X}).

It should be noted that techniques for the explicit learning of the stochastic projection p, diffeomorphism g, and the local coordinate chart ϕ exist. However, we notice that, since (ϕ_{f}, ϕₓ, p, g)∈ [symbol] ^{∞} (where [symbol] ^{∞} denotes the set of infinitely differentiable functions), \hat{f}=ϕ_{f}ºgº ϕₓ⁻¹ºp as a whole is a continuously differentiable function on a compact subset of [symbol] n², and can therefore be approximated with theoretical guarantee by the universal approximation theorem.

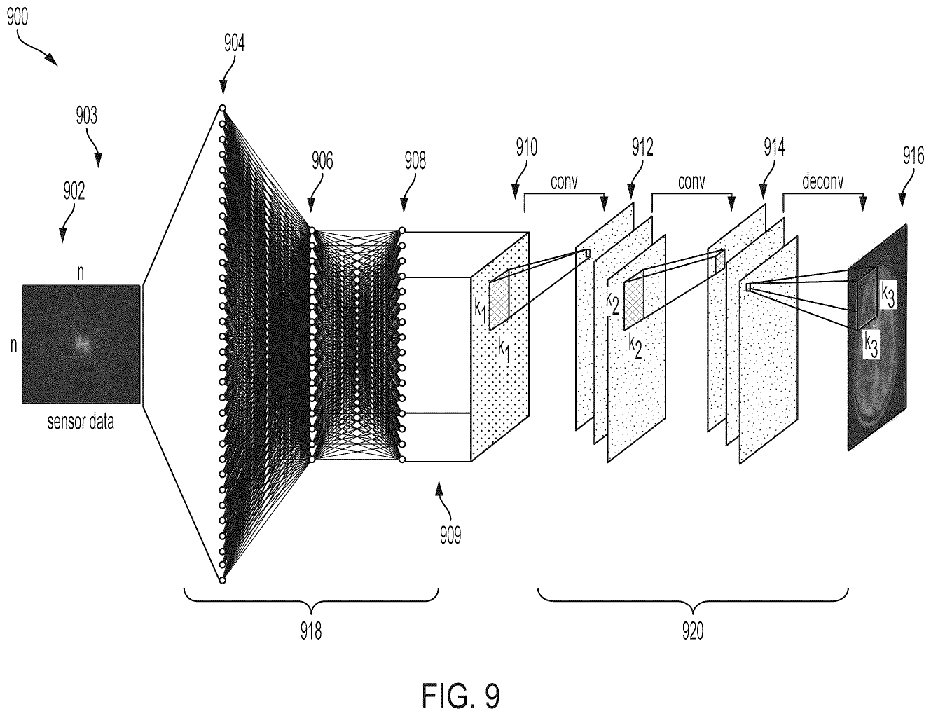

FIG. 9 shows a system diagram representing an example neural network model 900 that can be used to reconstruct an image by transforming data from a sensor domain to an image domain. The model 900 can implement AUTOMAP image processing and, thereby, can be configured to transform sensor data (e.g., sensor data 802 of FIG. 8) from the sensor domain into the image domain, thereby reconstructing the sensor data into an image. The model 900 provides an example implementation of a data-driven, manifold learning approach as described above in connection with FIG. 8.

The sensor data 902 may be arranged in an “n×n” matrix in the sensor domain 903. The model 900 is shown to include a plurality of fully connected layers 918, including an input layer 904, a first hidden layer 906, and a second hidden layer 908. The fully connected layers 918 can approximate the between-manifold projection of sensor data 902 from the sensor domain 903 to the image domain 909. In this way, the fully connected layers 918 produce an “n×n” matrix 910. The matrix 910 can then processed by a plurality of convolutional layers 920, as shown, which can include both a first convolutional layer 912 and second convolutional layer 914, used to produce a reconstructed image at an output layer 916. Here, “n” represents the number of data points along a single dimension of the sensor data 902.

The sensor data 902 may include a vector or matrix of sensor domain sampled data produced, for example, by an imaging system (e.g., one of the imaging systems of FIGS. 1-7). The input layer 904 may be fully connected to the first hidden layer 906, which may allow the sensor data 902 to be vectorized in any order. Complex data in the sensor data 902 (e.g., such as MR data) may be separated into real and imaginary components and concatenated in an input vector at input layer 904. As a result, the “n×n” matrix of the sensor data 902 may be reshaped to a “2n²×1” real-valued vector (e.g., the input vector) containing both the real and imaginary components of the sensor data 902. The input layer 904 may be fully connected to the “n²×1” first hidden layer 906 that is activated by an activation function (e.g., a non-linear activation function such as the hyperbolic tangent function). The first hidden layer 906 may be fully connected to a second “n²×1” hidden layer 908, which may produce a “n×n” matrix 910 when applied to the output of the first hidden layer 906. Each of the fully connected layers 918 may represent affine mapping (e.g., matrix multiplication) followed by non-linearity (e.g., an activation function). For example, the non-linearity applied during the application of the first hidden layer 906 to the input vector (e.g., to the nodes of the input vector) may be represented by the following equation:

g(χ=s(W_{χ}+b)

In the above equation, g(x) is a matrix (e.g., the nodes/output of the first hidden layer) resulting from the application of the first hidden layer 906 to the input vector, where x is the input vector (e.g., the nodes/output of the input layer), where W is a d′×d weight matrix, where b is an offset vector of dimensionality d′, and where s is the activation function (e.g., the hyperbolic activation function). The non-linearity applied during the application of the second hidden layer 908 to the output of the first hidden layer 906 (e.g., to the nodes of the first hidden layer) may be similarly represented.

The first convolutional layer 912 may apply a predetermined number of filters to the matrix 910 followed by a rectifier nonlinearity. The second convolutional layer 914 may apply a predetermined number of filters to the output of the first convolutional layer 912 followed by a rectifier nonlinearity. The output of the second convolutional layer 914 may be de-convolved with a predetermined number of filters by applying the output layer 916 to produce a reconstructed image in the image domain (e.g., as an “n×n” matrix). In this way, the first and second convolutional layers 912, 914 may be applied to perform feature extraction after the sensor data 902 is transformed from the sensor domain 903 into the image domain 909.

The model 900 can be trained to perform image reconstruction before being implemented. For example, an image may be transformed from the image domain 909 to a given sensor domain 903 (e.g., frequency domain, Radon domain, etc.) using known operations to produce sensor data 902. This sensor data 902 may then be input into and processed by model 900 to perform training. The output of model 900 may then be analyzed and compared to the original image to determine the amount of error present in the reconstructed image. The weights of the networks within the model 900 (e.g., the weights between layers 904 and 906 and between layers 906 and 908) may then be adjusted, and then this training process may be repeated with a new training image. For example, the training process may be repeated a predetermined number of times or may be repeated until the amount of observed error in the reconstructed image is observed to be below a certain threshold.

For instances in which the model 900 is intended to be used for a particular image reconstruction purpose (e.g., reconstructing images of the human brain), it may be beneficial to train the model 900 using images related to that purpose (e.g., using images of the human brain). This image-based training specialization may result in improved hidden-layer activation sparsity for fully connected layers 918 of the model 900 without the need to impose a sparsifying penalty on these layers. Improving hidden layer activation sparsity in this way may provide benefits over comparatively dense hidden layer activations. For example, these benefits may include reduced information entangling, more efficient variable-size representation, improved likelihood of linear separability, and improved efficiency, compared to dense hidden layer activations.

The nature of the fully connected layers 918 of the model 900 can present certain limitations with respect to the versatility of the model 900. For example, model 900 may require significant usage of graphics processing unit (GPU) random-access memory (RAM) if presented with the task of reconstructing large matrix size magnetic resonance (MR) datasets to the point where the use of model 900 to reconstruct the large datasets becomes impractical. However, a patch-based image reconstruction approach can be implemented such that model 900 can be used to practically process larger datasets.

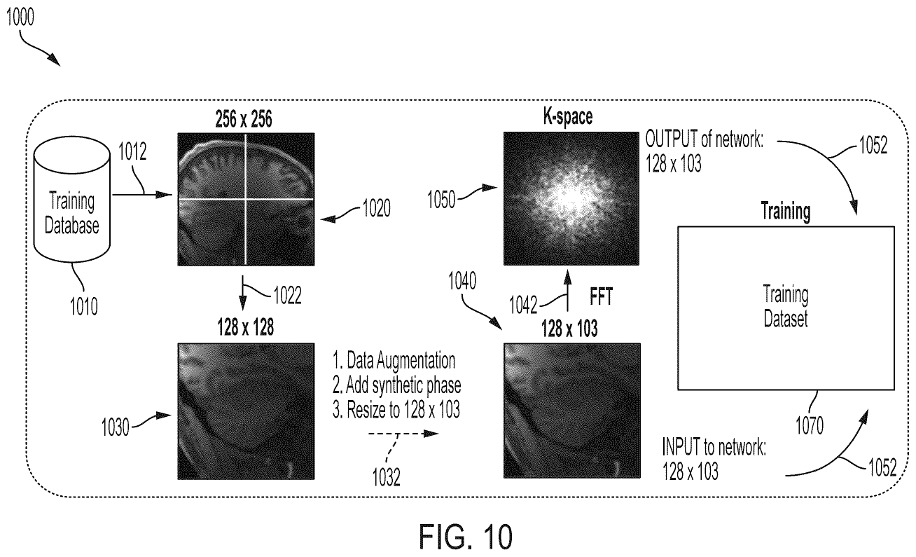

FIG. 10 shows a flow diagram illustrating an example process 1000 for generating an example training dataset 1070. The training dataset 1070 can be used to train model 900 (or another similar type of model or models) such that model 900 can learn how to reconstruct images by processing multiple patches of data and subsequently assembling the different patches into a reconstructed image. Process 1600 can be performed by a variety of different systems, such as any of the imaging systems of FIGS. 1-7 as detailed above.

At 1012, process 1000 can receive a training image 1020 from a training database 1010. The training database 1010 can be implemented in a variety of different ways, depending on the intended application for training the model 900. For example, the training database 1010 can be a public database of brain MR images, such as a database associated with the Human Connectome Project (HCP). The training database 1010 can include one or more different datasets including different data samples. For example, an image dataset including the training image 1020 can be assembled from 102,000 2D T₁-weighted brain MR images selected from the HCP public database. The samples in the image dataset can also be MR images of different organs, such as heart MR images, among other types of possible images. In some examples, samples in the image dataset can be cropped at 1012, such as cropping the training image 1020 to be an image of resolution 256×256 pixels. The training image 1020 is in the image domain as opposed to the sensor domain.

At 1022, process 1000 can subsample the training image 1020 to separate the training image 1020 into separate image patches. FIG. 10 illustrates an example image patch 1030 associated with the bottom left quadrant of the training image 1020. For example, process 1000 can the training image 1020 into four separate images each of resolution 128×128 pixels. Depending on the application, different quantities and configurations of patches can be generated at 1022 to fit appropriate memory and computing parameters. By processing the smaller image patch 1030 instead of the full training image 1020, computing power and memory usage for the model 900 can be reduced to practical levels.

At 1032, process 1000 can add synthetic phase modulation to each of the separate image patches generated at 1022 to generate complex image patches. By adding the synthetic phase modulation to the image patch 1030, for example, complex-valued data (e.g., data including both real and imaginary components) can be generated for the image patch 1030. The complex-valued data generated as a result of the synthetic phase modulation can then be represented in the sensor domain. Also, at 1032, process 1000 can perform any of a variety of suitable data augmentation steps to reduce overfitting when ultimately training the model 900. Moreover, process 1000 can resize the image patches at 1032 for various purposes. For example, process 1000 can resize the image patch 1030 to be an image of resolution 123×103 pixels. FIG. 10 illustrates an example complex image patch 1040 generated from the image patch 1030, where the complex image patch 1040 includes added synthetic phase and any desired data augmentation. The complex image patch 1040 is also resized to be an image of resolution 123×103 pixels.

At 1042, process 1000 can apply a Fourier transform to the complex image patches to generate sensor data patches in the sensor domain for each of the complex image patches. For example, process 1000 can apply an inverse Fourier transform function (e.g., MATLAB 2D FFT, etc.) to the complex image to generate an example sensor data patch 1050 as shown in FIG. 10. The sensor data patch 1050 is in the sensor domain as opposed to the image domain, and includes both real and imaginary components representative of the image patch 1030. For example, the sensor data patch 1050 can include k-space MR data similar to sensor data 902 that is provided as input to model 900. Since the sensor data patch 1050 is smaller in size than sensor data that would be generated as a result of applying a Fourier transform to the initial training image 1020, the sensor data patch 1050 can be more practically and efficiently processed (e.g., in terms of computing power and memory usage) by the model 900 than the sensor data that would be generated as a result of applying a Fourier transform to the initial training image 1020. Also, at 1042, random noise, such as additive white Gaussian noise (AWGN), can be added to the sensor data patches to simulate real sensor data (e.g., sensor data 902). The random noise can be noise ranging from 20 decibels (dB) to 45 decibels.

At 1052, the complex image patches generated at 1032 and the corresponding sensor data patches generated at 1042 can be added to the training dataset 1070. For example, the training dataset 1070 can include an input-output pair comprised of the sensor data patch 1050 as an input and the complex image patch 1040 as an output. Then, the training dataset 1070 can be used to train the model 900 (or another similar type of model) such that the model 900 is taught to generate the complex image patch 1040 responsive to receiving the sensor data patch 1050. For example, different weights used in model 900 (e.g., the weight(s) between the input layer 904 and the first hidden layer 906, the weight(s) between the first hidden layer 906 and the second hidden layer 908) can be adjusted after applying the training dataset 1070 to the model 900 such that the model 900 learns to generate accurate image patches responsive to receiving sensor data patches. Process 1000 can be repeated for each sample image in the image dataset to build up the training dataset 1070. The training dataset 1070 can accordingly include a set of input-output pairs, where each input-output pair of the set of input-output pairs includes a sensor data patch and a corresponding image patch.

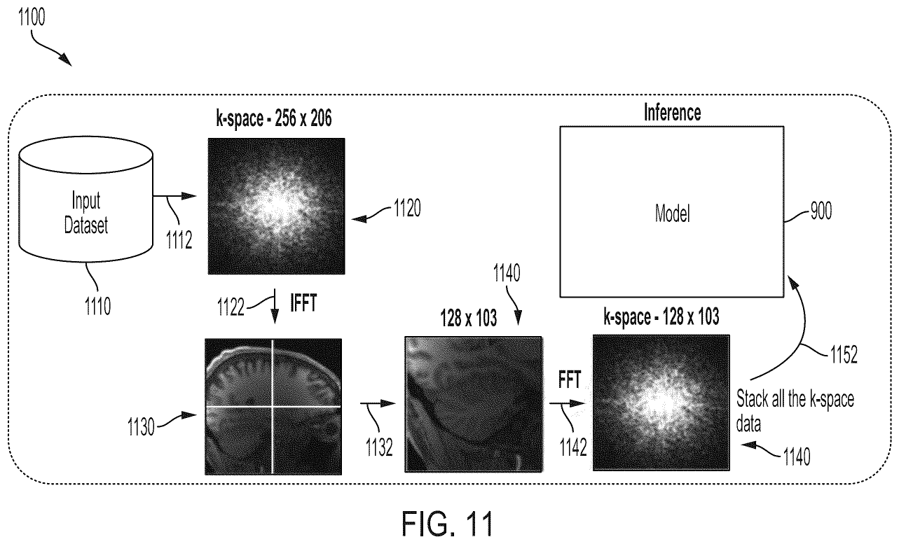

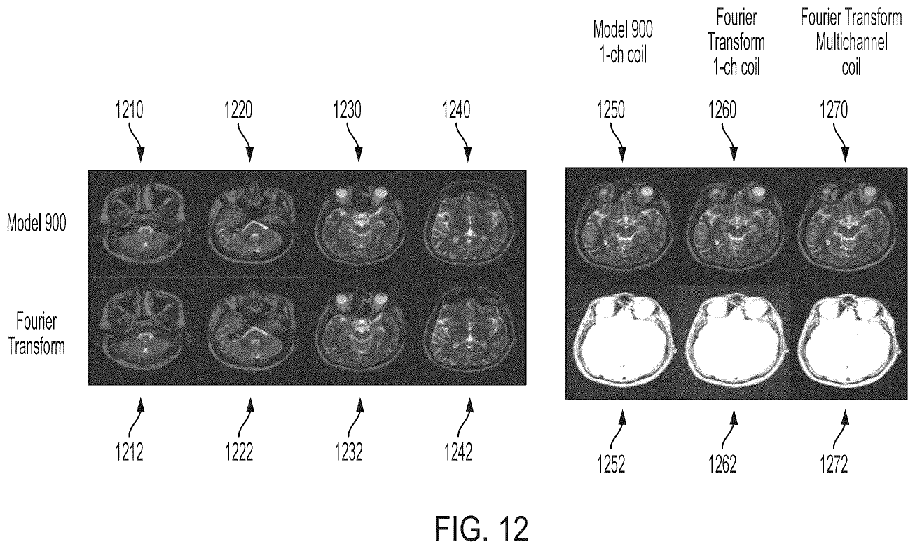

FIG. 11 shows a flow diagram illustrating an example process 1100 for performing inference using a model trained based on the training dataset 1070. For example, after the model 900 (or another similar type of model) has been trained using the training dataset 1070, process 1100 can be performed using the model 900. The outputs generated by the model 900 using process 1100 can then be analyzed to determine whether training the model 900 using the training dataset 1070 allows the model 900 to generate accurate images in response to receiving complex input data that is split into different patches. Example results are shown and discussed below with respect to FIGS. 12-15.

At 1112, process 1100 can receive input sensor data 1120 from a complex input dataset 1110. The complex input dataset 1110 can be, for example, an in vivo, raw, large matrix size MR dataset associated with a patient. The complex input dataset 1110 can include different patches, slices, etc. that together form the complete complex input dataset 1110. For example, the complex input dataset 1110 can include a collection of different slices of brain MR data acquired using a single channel MR volume coil. The complex input dataset 1110 can be k-space data in the sensor domain including both real and imaginary components. The complex input dataset 1110 can be accessed via a database, for example. The input sensor data 1120 can be a 256×206 matrix in the sensor domain, for example.

At 1122, process 1100 can covert the input sensor data 1120 from the sensor domain to the image domain. For example, at 1122, process 1100 can apply a Fourier transform to the input data patch 1120 to generate an input image 1130, as shown in FIG. 11. Accordingly, input image 1130 can be an MR brain image of resolution 256×206 pixels. Process 1100 can apply an inverse Fourier transform function (e.g., MATLAB 2D FFT, etc.) to the input sensor data 1120 to transform the input sensor data 1120 to the input image 1130, for example.

At 1132, process 1100 can split the input image 1130 into separate image patches. For example, as shown in FIG. 11, process 1100 can split the input image 1130 into four separate patches including an upper-right quadrant, an upper-left quadrant, a lower-right quadrant, and a lower-left quadrant. FIG. 11 shows an example input image patch 1140 that is representative of the lower-left quadrant of the input image 1130. By reducing the size of the input image 1130 in this manner, the input data ultimately provided to the model 900 can be more efficiently processed.

At 1142, process 1100 can convert each of the separate image patches generated at 1132 back into the sensor domain. For example, process 1100 can apply a Fourier transform to each of the separate image patches representative of the four quadrants of the input image 1130, including the input image patch 1140. Process 1100 can apply a Fourier transform function to the input image patch 1140 to convert the input image patch 1140 back into the sensor domain to generate an example sensor data patch 1150, as shown in FIG. 11. The sensor data patch 1150 can include k-space MR data, including both real and imaginary components representative of the input image patch 1140, that is provided as input to model 900. The sensor data patch 1140 can accordingly be a 128×103 matrix in the sensor domain.

At 1152, process 1100 can provide the sensor data patches generated at 1142, including the sensor data patch 1140, as input to the model 900. Then, the corresponding image patch outputs of the model 900 can be assembled together into a full image and analyzed as part of an inference experiment to test the accuracy of the model 900 in generating medical images after being trained using the training dataset 1070. Since the model 900 processes smaller patches of data (in this example 128×103 matrices), efficiencies in terms of memory usage can be achieved. The results of the inference experiment are discussed in more detail below.

FIG. 12 shows a first series of medical images generated using different approaches. Specifically, FIG. 12 shows T2-weighted fast spin echo (FSE) MR brain images that are generated with a single-channel volume coil. FIG. 12 also shows a comparison of a single slice dataset that is reconstructed using different approaches along with corresponding low window-level images. The input sensor data used to generate the images shown in FIG. 12 (e.g., the sensor data 902) was acquired on a healthy patient using parameters of 1.5 Tesla (1.5 T), a repetition time (TR) of 7000 milliseconds (ms), a time to echo (TE) of 107 ms, a matrix size of 256×206, a slice thickness of 4.5 millimeters (mm), and a slice count of 22 total slices.

As shown in FIG. 12, each of the images 1210, 1220, 1230, and 1240 are generated using the model 900 after the model 900 has been trained using the training dataset 1070. The images 1210, 1220, 1230, and 1240 show different brain image slices of the 22-slice input sensor dataset. Each of the images 1212, 1222, 1232, and 1242 show corresponding images generated as a result of using a Fourier transform reconstruction process as opposed to using model 900. Also, the image 1250 shows a single slice brain image reconstructed using the model 900 and a single-channel volume coil. The image 1252 shows the corresponding low window-level image associated with the image 1250. The image 1260 then shows a single slice brain image reconstructed using a Fourier transform reconstruction process (as opposed to using the model 900) and a single-channel volume coil. The image 1262 shows the corresponding low window-level image associated with the image 1260. The image 1270 further shows a single slice brain image reconstructed using a Fourier transform reconstruction process and a multi-channel volume coil. The image 1272 shows the corresponding low window-level image associated with the image 1260. From the images shown in FIG. 12, it can be seen that significant noising is observed when using the trained model 900 to reconstruct medical images.

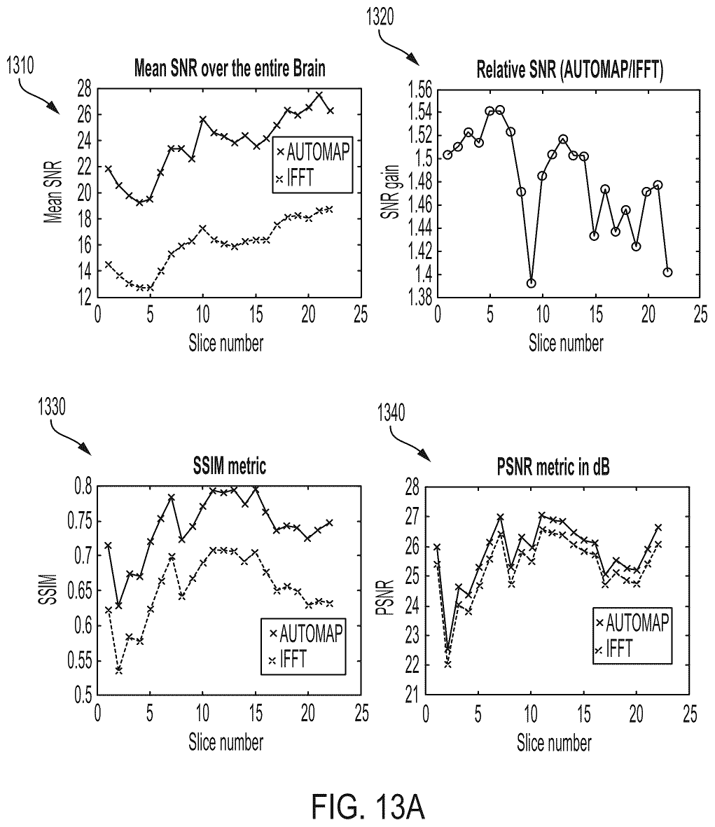

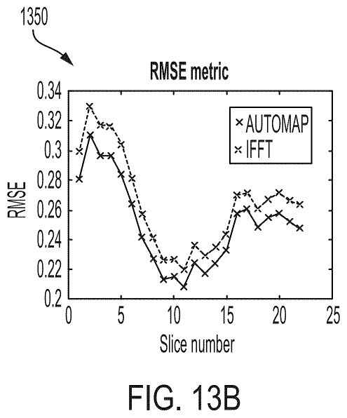

FIGS. 13A-13B show a first series of graphs plotting data associated with the medical images shown in FIG. 12. The graph 1310, specifically, shows the mean signal-to-noise (SNR) ratio (calculated by dividing the signal magnitude by the standard deviation of the noise) over the entire brain (over all 22 slices), plotted for both the model 900 using a single-channel volume coil and for a Fourier transform reconstruction process using a single-channel volume coil. The graph 1320 shows the relative SNR gain (model 900/Fourier transform) across each of the 22 slices. The graph 1330 shows plots for a structure similarity Index for measuring image quality (SSIM) metric over the entire brain, plotted for both the model 900 using a single-channel volume coil and for a Fourier transform reconstruction process using a single-channel volume coil. The graph 1340 shows a peak signal-to-noise ratio (PSNR) metric over the entire brain, plotted for both the model 900 using a single-channel volume coil and for a Fourier transform reconstruction process using a single-channel volume coil. The graph 1350 shows a root mean square error (RMSE) metric over the entire brain, plotted for both the model 900 using a single-channel volume coil and for a Fourier transform reconstruction process using a single-channel volume coil.

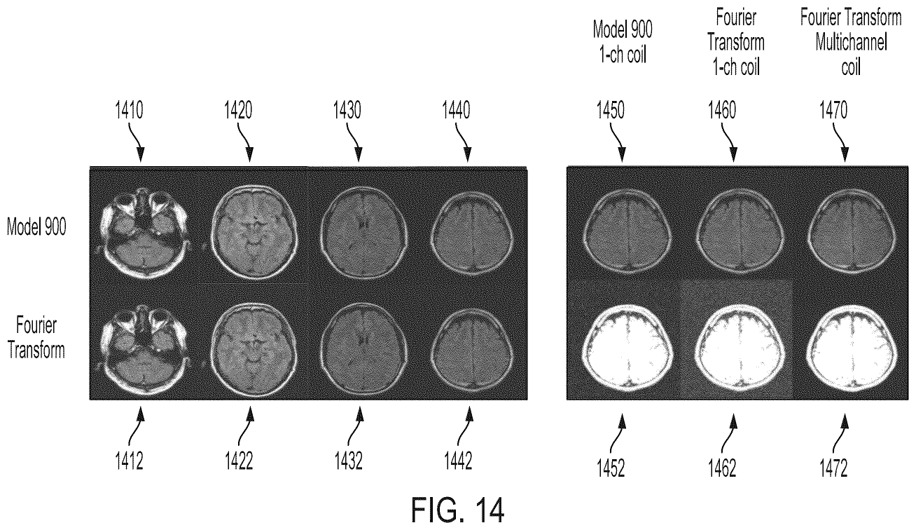

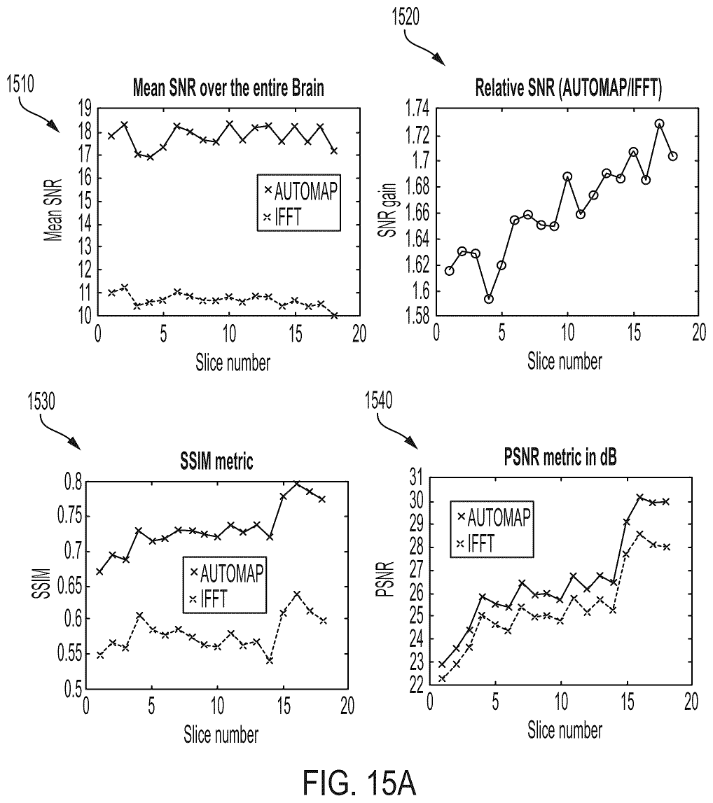

FIG. 14 shows a second series of medical images generated using different approaches. Specifically, FIG. 12 shows T2-weighted fluid-attenuated inversion recovery (FLAIR) MR brain images that are generated with a single-channel volume coil. The input sensor data used to generate the images shown in FIG. 14 (e.g., the sensor data 902) was acquired on a healthy patient using parameters of 1.5 T, a TR of 9000 ms, a TE of 118 ms, a matrix size of 256×192, a slice thickness of 5 mm, and a slice count of 18 total slices.

As shown in FIG. 14, each of the images 1410, 1420, 1430, and 1440 are generated using the model 900 after the model 900 has been trained using the training dataset 1070. The images 1410, 1420, 1430, and 1440 show different brain image slices of the 18-slice input sensor dataset. Each of the images 1412, 1422, 1432, and 1442 show corresponding images generated as a result of using a Fourier transform reconstruction process as opposed to using model 900. Also, the image 1450 shows a single slice brain image reconstructed using the model 900 and a single-channel volume coil. The image 1452 shows a corresponding low window-level image associated with the image 1450. The image 1460 shows a single slice brain image reconstructed using a Fourier transform reconstruction process and a single-channel volume coil. The image 1462 shows the corresponding low window-level image associated with the image 1460. The image 1470 further shows a single slice brain image reconstructed using a Fourier transform reconstruction process and a multi-channel volume coil. The image 1472 shows the corresponding low window-level image associated with the image 1460. From the images shown in FIG. 14, it again can be seen that significant noising is observed when using the trained model 900 to reconstruct medical images.

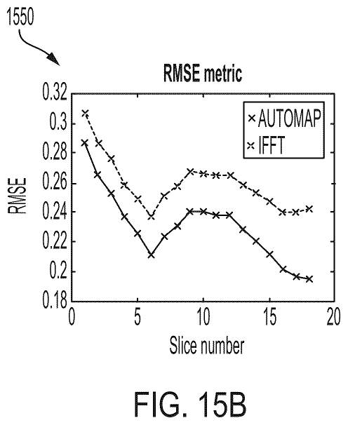

FIGS. 15A-15B show a second series of graphs plotting data associated with the medical images shown in FIG. 14. The graph 1510, specifically, shows the mean SNR ratio over the entire brain (over all 18 slices), plotted for both the model 900 using a single-channel volume coil and for a Fourier transform reconstruction process using a single-channel volume coil. The graph 1520 shows the relative SNR gain across each of the 18 different slices. The graph 1530 shows plots for the SSIM metric over the entire brain, plotted for both the model 900 using a single-channel volume coil and for a Fourier transform reconstruction process using a single-channel volume coil. The graph 1540 shows the PSNR metric over the entire brain, plotted for both the model 900 using a single-channel volume coil and for a Fourier transform reconstruction process using a single-channel volume coil. The graph 1550 shows the RMSE metric over the entire brain, plotted for both the model 900 using a single-channel volume coil and for a Fourier transform reconstruction process using a single-channel volume coil.

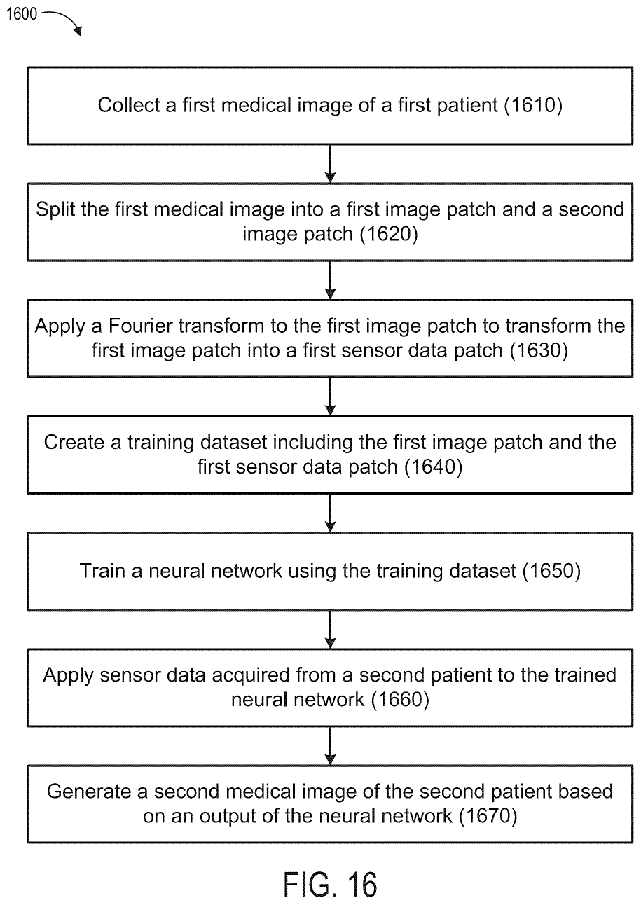

FIG. 16 shows a flow diagram illustrating an example process 1600 for medical imaging. The process 1600 can be performed by a variety of different systems, such as any of the imaging systems of FIGS. 1-7 as detailed above. Moreover, machine-readable instructions for performing process 1600 can be provided via a variety of different types of computer-readable media, including non-transitory computer-readable media. Process 1600 can be used to improve the accuracy of various image reconstruction processes for medical imaging applications training a neural network (e.g., the model 900) using smaller patches of medical sensor data. As a result, the neural network can become more flexible in that it can be used for more different applications. For example, the model 900 may require significant usage of GPU RAM if presented with the task of reconstructing large matrix size MR datasets to the point that using the model 900 to reconstruct the large datasets in some cases becomes impractical. However, process 1600 can be implemented such that the model 900 can in fact be used to practically process larger datasets.

At 1610, process 1600 can collect a first medical image of a first patient. For example, process 1600 can receive the training image 1020 from the training database 1010. The training database 1010 can be a public database of brain MR images, such as a database associated with the Human Connectome Project (HCP). The training database 1010 can include different datasets including different data samples. For example, an image dataset including the first medical image of the first patient can be assembled from a collection of 2D T1-weighted brain MR images. The samples in the image dataset can also be MR images of different organs, such as heart MR images, among other types of possible images. At 1620, the first medical image of the first patient can be cropped. For example, the first medical image of the first patient can be cropped to a be an image of resolution 256×256 pixels. The first medical image of the first patient is in the image domain as opposed to the sensor domain.

At 1620, process 1600 can split the first medical image into a first medical image patch and a second medical image patch. For example, process 1600 can split the training image 1020 into the image patch 1030 associated with the bottom left quadrant of the training image 1020 and a second image patch associated with the bottom right quadrant of the training image 1020. At 1620, process 1600 can split the first medical image in any number of ways depending on the application, to generate any desired number of medical image patches of more suitable size for processing efficiently by a neural network or other type of machine learning model. The first medical image patch and the second medical image patch can each be images of resolution 128× 128 pixels, for example. Process 1600 can manipulate the first image patch (and any/all other image patches) in various ways. For example, process 1600 can add synthetic phase to the first image patch, resize the first image patch, and/or perform any desired data augmentation on the first data patch. For example, at 1630, process 1600 can generate the complex image patch 1040 from the image patch 1030.

At 1630, process 1600 can apply a Fourier transform to the first image patch to transform the first image patch into a first sensor data patch, where the first sensor data patch is in the sensor domain as opposed to the image domain. For example, process 1600 can apply a Fourier transform to the complex image patch 1040 to transform the complex image patch 1040 into the sensor data patch 1050. The first sensor data patch generated at 1630 can include both real and imaginary components representative of the first image patch. For example, the first sensor data patch can include a matrix of k-space MR data of size 128×103, 128×128, and other size matrices corresponding to the first image patch. Process 1600 can add random noise to the first sensor data patch at 1630, such as AWGN ranging from 20 dB to 45 dB in some examples. Fourier transforms can also be applied to any additional image patches created at 1620, including the second image patch, to convert any/all of the image patches into sensor data patches.

At 1640, process 1600 can create a training dataset including the first image patch and the first sensor data patch. For example, process 1600 can create the training dataset 1070 and include both the complex image patch 1040 and the sensor data patch 1050 as an input-output pair in the training dataset 1070. Process 1600 can also add image-sensor data pairs associated with any/all additional patches created from the first medical image of the first patient at 1620. For example, the second image patch and a corresponding second sensor data patch can be added to the training dataset 1070 as an input-output pair.

At 1650, process 1600 can train a neural network using the training dataset. For example, process 1600 can train the model 900 using the training dataset 1070. By training the model 900 using the training dataset 1070, the model 900 can learn to interpret different patches of medical images (e.g., different slices of the brain, different slices of the heart, etc.) such that the model 900 can accurately generate medical images based on a series of different patches it receives as input. In this manner, the model 900 can become more flexible such that it can be used for more different applications with different types and sizes of input data (e.g., input data 902). In training the neural network using the training dataset, the first sensor data patch can be provided as input to the neural network and the first sensor data patch can be associated with the first image patch as the output of the neural network. That is, the neural network can effectively be taught to generate the first image patch as the output image when it receives the first sensor data patch as the input data. For example, when training the model 900 using the training dataset 1070, the weights between the fully connected layers 918 can be adjusted such that the model 900 produces the desired outputs defined by the training dataset 1070.

At 1660, process 1600 can apply sensor data acquired from a second patient to the trained neural network. For example, process 1600 can apply sensor data 902 to the model 900 after the model 900 has been trained with the training dataset 1070. The sensor data acquired from the second patient and applied to the trained neural network at 1660 can advantageously be provided in patches (slices) that are appropriately sized for processing by the neural network. For example, the sensor data acquired from the second patient and applied to the trained neural network at 1660 can be a matrix of k-space MR data of the same size as the first sensor data patch in the training dataset used to train the neural network. Since the neural network has been appropriately trained, the neural network can accurately interpret sensor data patches applied at 1660.

At 1670, process 1600 can generate a second medical image of the second patient based on an output of the neural network. For example, process 1600 can generate the second medical image of the second patient based on an output of the model 900 provided via the output layer 916. As demonstrated by the data shown and described with respect to FIGS. 12-15, the patch-based reconstruction of the second medical image using process 1600 can provided high quality medical images with significant denoising potential when compared to alternative approaches such as using a Fourier transform to generate the second medical image based on the sensor data acquired from the second patient. The second medical image can then be displayed for clinical analysis.

Using the data-driven manifold learning techniques described above, as opposed to conventional data transformation techniques such as the Discrete Fourier Transform, the domain for signal acquisition may be comparatively more flexible and can be more tailored to the underlying physical system. This generalized reconstruction can compensate for hardware imperfections such as gradient nonlinearity in Mill by being trained on the system being used. These and other imaging artifacts can be compensated for by the trained neural network. Also, generalized reconstruction may have higher noise immunity and reduced under sampling error when appropriately trained, allowing for greatly accelerated image capture. Additionally, non-intuitive Pulse sequences (e.g., for MRI applications) may be generated by data-driven manifold learning because the signals can be acquired in a non-intuitive domain before reconstruction. Further, pulse sequences can be tailored in real-time in response to specific individual subjects or samples. Training may, for example, be performed with large public or private image databases (e.g., PACS, Human Connectome Project, etc.).

It will be appreciated that this description uses examples to disclose the invention and also to enable any person skilled in the art to practice the invention, including making and using any devices or systems and performing any incorporated methods. The patentable scope of the invention is defined by the claims and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A method for medical imaging, comprising:
collecting a first medical image of a first patient from a database;
splitting the first medical image into a first image patch and a second image patch;
applying a Fourier transform to the first image patch to transform the first image patch into a first sensor data patch;
creating a training dataset comprising the first image patch and the first sensor data patch;
training a neural network using the training dataset;
after training the neural network using the training dataset, applying sensor data acquired from a second patient using a medical imaging system as an input to the neural network;
generating a second medical image of the second patient based on an output of the neural network; and
displaying the second medical image of the second patient for clinical analysis.

2. The method of claim 1, further comprising adding synthetic phase to the first image patch before applying the Fourier transform to the first image patch to transform the first image patch into the first sensor data patch.

3. The method of claim 1, further comprising resizing the first image patch before applying the Fourier transform to the first image patch to transform the first image patch into the first sensor data patch.

4. The method of claim 1, further comprising adding random noise to the first sensor data patch before creating the training dataset.

5. The method of claim 1, wherein training the neural network using the training dataset comprises providing the first sensor data patch as the input to the neural network and associating the first sensor data patch with the first image patch as the output of the neural network.

6. The method of claim 2, wherein the first sensor data patch comprises complex-valued magnetic resonance k-space data.

7. The method of claim 1, wherein the neural network comprises a data-driven, manifold learning neural network.

8. The method of claim 1, further comprising:
applying the Fourier transform to the second image patch to transform the second image patch into a second sensor data patch; and
adding the second image patch and the second sensor data patch to the training dataset before training the neural network using the training dataset.

9. The method of claim 1, further comprising:
before applying the sensor data acquired from the second patient as the input to the neural network, splitting the sensor data acquired from the second patient into a third sensor data patch and a fourth sensor data patch;
wherein applying the sensor data acquired from the second patient as the input to the neural network comprises first applying the third sensor data patch as the input to the neural network and subsequently applying the fourth sensor data patch as the input to the neural network.

10. A non-transitory computer-readable storage medium having instructions stored thereon that, when executed by at least one processor, cause the at least one processor to implement operations comprising:
collecting a first medical image of a first patient from a database;
splitting the first medical image into a first image patch and a second image patch;
applying a Fourier transform to the first image patch to transform the first image patch into a first sensor data patch;
creating a training dataset comprising the first image patch and the first sensor data patch;
training a neural network using the training dataset;
after training the neural network using the training dataset, applying sensor data acquired from a second patient using a medical imaging modality as an input to the neural network;
generating a second medical image of the second patient based on an output of the neural network; and
displaying the second medical image of the second patient for clinical analysis.

11. The computer-readable medium of claim 9, the operations further comprising:
adding synthetic phase to the first image patch before applying the Fourier transform to the first image patch to transform the first image patch into the first sensor data patch; and
resizing the first image patch before applying the Fourier transform to the first image patch to transform the first image patch into the first sensor data patch; and
adding random noise to the first sensor data patch before creating the training dataset;
wherein the first sensor data patch comprises complex-valued magnetic resonance k-space data and the neural network comprises a data-driven, manifold learning neural network.

12. A system comprising:
a display;
one or more sensors;
one or more processors; and
one or more non-transitory computer readable storage media having instructions stored thereon that, when executed by the one or more processors, cause the one or more processors to implement operations comprising:
collecting a first medical image of a first patient from a database;
splitting the first medical image into a first image patch and a second image patch;
applying a Fourier transform to the first image patch to transform the first image patch into a first sensor data patch;
creating a training dataset comprising the first image patch and the first sensor data patch;
training a neural network using the training dataset;
after training the neural network using the training dataset, applying sensor data acquired from a second patient as an input to the neural network;
generating a second medical image of the second patient based on an output of the neural network; and
causing the display to display the second medical image of the second patient for clinical analysis.

13. The system of claim 12, the operations further comprising:
adding synthetic phase to the first image patch before applying the Fourier transform to the first image patch to transform the first image patch into the first sensor data patch; and
adding random noise to the first sensor data patch before creating the training dataset.

14. The system of claim 12, the operations further comprising resizing the first image patch before applying the Fourier transform to the first image patch to transform the first image patch into the first sensor data patch.

15. The system of claim 12, wherein:
the first sensor data patch comprises complex-valued magnetic resonance k-space data; and
the neural network comprises a data-driven, manifold learning neural network.

16. A method for training a neural network for medical imaging, comprising:
collecting a medical image of a patient from a database;
splitting the medical image into at least a first image patch and a second image patch;
applying a Fourier transform to the first image patch to transform the first image patch into a first sensor data patch;
applying a Fourier transform to the second image patch to transform the second image patch into a second sensor data patch;
creating a training dataset comprising the first image patch and the first sensor data patch, and the second image patch and the second sensor data patch; and
training a neural network using the training dataset.

17. The method of claim 16, further comprising:
adding synthetic phase to the first image patch before applying the Fourier transform to the first image patch to transform the first image patch into the first sensor data patch; and
adding synthetic phase to the second image patch before applying the Fourier transform to the second image patch to transform the second image patch into the second sensor data patch.

18. The method of claim 16, further comprising:
resizing the first image patch before applying the Fourier transform to the first image patch to transform the first image patch into the first sensor data patch; and
resizing the second image patch before applying the Fourier transform to the second image patch to transform the second image patch into the second sensor data patch.

19. The method of claim 16, further comprising:
resizing the first image patch before applying the Fourier transform to the first image patch to transform the first image patch into the first sensor data patch; and
resizing the second image patch before applying the Fourier transform to the second image patch to transform the second image patch into the second sensor data patch.

20. The method of claim 16, further comprising adding random noise to the first sensor data patch and to the second sensor data patch before creating the training dataset.

21. The method of claim 16, wherein training the neural network using the training dataset comprises providing the first sensor data patch as the input to the neural network and associating the first sensor data patch with the first image patch as the output of the neural network and subsequently providing the second sensor data patch as the input to the neural network and associating the second sensor data patch with the second image patch as the output of the neural network.

22. The method of claim 16, wherein the first sensor data patch and the second sensor data patch both comprise complex-valued magnetic resonance k-space data.

23. The method of claim 16, wherein the neural network comprises a data-driven, manifold learning neural network.

24. A method for medical imaging, comprising:
acquiring sensor data from a patient using a medical imaging system;
splitting the sensor data from the patient into a first sensor data patch and a second sensor data patch;
applying the first sensor data patch as an input to a neural network that has been trained using a training dataset comprising a set of input-output pairs, wherein each input-output pair of the set of input-output pairs comprises a sensor data patch and a corresponding image patch;
receiving a first image patch as an output of the neural network responsive to applying the first sensor data patch as the input to the neural network;
applying the second sensor data patch as the input to the neural network;
receiving a second image patch as the output of the neural network responsive to applying the second sensor data patch as the input to the neural network;
generating a medical image of the patient using both the first image patch and the second image patch; and
causing the medical image of the patient to be displayed for clinical analysis.

25. The method of claim 24, wherein the sensor data acquired from the patient comprises magnetic resonance k-space data.

26. The method of claim 24, wherein the neural network comprises a data-driven, manifold learning neural network.

27. The method of claim 24, wherein the sensor data patch comprises synthetically added random noise.

28. The method of claim 24, wherein generating the medical image of the patient using both the first image patch and the second image patch comprises stitching the first image patch and the second image patch together.
